(19) United States
(12) Patent Application Publication
(10) Pub. No.: US 2025/0386577 A1
(43) Pub. Date: Dec. 18, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Hiroaki KATOU, Nonoichi Ishikawa (JP); Tsuyoshi KACHI, Kanazawa Ishikawa (JP); Kazuyuki SATO, Nonoichi Ishikawa (JP); Toshifumi NISHIGUCHI, Hakusan Ishikawa (JP)

(21) Appl. No.: 18/952,260

(22) Filed: Nov. 19, 2024

(30) Foreign Application Priority Data
Jun. 18, 2024 (JP) 2024-098264

(51) Int. Cl. H10D 64/00; H10D 30/66; H10D 64/66

(52) U.S. Cl. CPC H10D 64/115; H10D 30/668; H10D 64/117; H10D 64/662

(57) ABSTRACT

A semiconductor device of embodiments includes: a semiconductor layer having a first face and a second face and including a first trench provided on a first face side; a first field plate electrode provided in the first trench; a gate electrode provided in a gate trench; a first electrode provided on the first face side of the semiconductor layer and electrically connected to the first field plate electrode; a second electrode provided on the second face side of the semiconductor layer; and a connection portion provided between the first electrode and the first field plate electrode, electrically connected to the first electrode and the first field plate electrode, and having an electrical resistance higher than an electrical resistance of the first field plate electrode.

### CROSS-REFERENCE TO RELATED APPLICATION

This application is based upon and claims the benefit of priority from Japanese Patent Application No. 2024-098264, filed on June 18, 2024, the entire contents of which are incorporated herein by reference.

### FIELD

Embodiments described herein relate generally to a semiconductor device.

### BACKGROUND

In order to reduce the size of a transistor or improve the performance of a transistor, a vertical transistor is used in which a gate electrode is buried in a trench provided in a semiconductor layer. In the vertical transistor, there is a trade-off between the drain-source breakdown voltage (hereinafter, also simply referred to as "breakdown voltage") and the on-resistance. That is, if the impurity concentration in the drift region is increased in order to reduce the on-resistance, the breakdown voltage decreases. Conversely, if the impurity concentration in the drift region is reduced in order to increase the breakdown voltage, the on-resistance increases.

As a method for solving the trade-off between the breakdown voltage and the on-resistance, a field plate electrode is provided in the trench of a vertical transistor. By changing the electric field distribution in the drift region using the field plate electrode, it is possible to increase the impurity concentration in the drift region while maintaining the breakdown voltage, for example. Therefore, it is possible to reduce the on-resistance while maintaining the breakdown voltage.

When the field plate electrode is electrically connected to the source electrode of the vertical transistor, a snubber circuit in which the electrical resistance between the source electrode and the field plate electrode and the capacitance between the field plate electrode and the semiconductor layer are connected in series is formed between the source electrode and the drain electrode. By providing the snubber circuit, it is possible to suppress ringing during the OFF operation of the vertical transistor.

### BRIEF DESCRIPTION OF THE DRAWINGS

FIG. 1 is a schematic cross-sectional view of a semiconductor device according to a first embodiment;

FIG. 2 is a schematic plan view of the semiconductor device according to the first embodiment;

FIG. 3 is a schematic cross-sectional view of a semiconductor device according to a comparative example;

FIG. 4 is a schematic plan view of the semiconductor device according to the comparative example;

FIG. 5 is an explanatory diagram of the function and effect of the semiconductor device according to the first embodiment;

FIG. 6 is a schematic cross-sectional view of a semiconductor device according to a modification example of the first embodiment;

FIG. 7 is a schematic cross-sectional view of a semiconductor device according to a second embodiment;

FIG. 8 is a schematic cross-sectional view of a semiconductor device according to a modification example of the second embodiment;

FIG. 9 is a schematic cross-sectional view of a semiconductor device according to a third embodiment;

FIG. 10 is a schematic cross-sectional view of a semiconductor device according to a modification example of the third embodiment;

FIG. 11 is a schematic cross-sectional view of a semiconductor device according to a fourth embodiment;

FIG. 12 is a schematic cross-sectional view of the semiconductor device according to the fourth embodiment;

FIG. 13 is a schematic cross-sectional view of a semiconductor device according to a fifth embodiment;

FIG. 14 is a schematic top view of the semiconductor device according to the fifth embodiment;

FIG. 15 is a schematic top view of a semiconductor device according to a first modification example of the fifth embodiment;

FIG. 16 is a schematic top view of a semiconductor device according to a second modification example of the fifth embodiment;

FIG. 17 is a schematic cross-sectional view of a semiconductor device according to a sixth embodiment;

FIG. 18 is a schematic plan view of the semiconductor device according to the sixth embodiment;

FIG. 19 is a schematic cross-sectional view of a semiconductor device according to a seventh embodiment; and

FIG. 20 is a schematic plan view of the semiconductor device according to the seventh embodiment.

### DETAILED DESCRIPTION

A semiconductor device of embodiments includes: a semiconductor layer having a first face and a second face opposite to the first face and including a first trench provided on a first face side, a gate trench provided on the first face side and surrounding the first trench, a first semiconductor region of a first conductive type, a second semiconductor region of a second conductive type provided between the first semiconductor region and the first face, and a third semiconductor region of the first conductive type provided between the second semiconductor region and the first face; a first field plate electrode provided in the first trench; a first field plate insulating layer provided between the first field plate electrode and the semiconductor layer; a gate electrode provided in the gate trench; a gate insulating layer provided between the gate electrode and the semiconductor layer; a first electrode provided on a side of the first face of the semiconductor layer and electrically connected to the third semiconductor region and the first field plate electrode; a second electrode provided on a side of the second face of the semiconductor layer and electrically connected to the first semiconductor region; and a connection portion provided between the first electrode and the first field plate electrode, electrically connected to the first electrode and the first field plate electrode, and having an electrical resistance higher than an electrical resistance of the first field plate electrode.

Hereinafter, embodiments will be described with reference to the diagrams. In addition, in the following description, the same or similar members and the like are denoted by the same reference numerals, and the description of the members and the like once described will be omitted as appropriate.

In addition, in the following description, when the notations of n⁺, n, n⁻, p⁺, p, and p⁻ are used, these notations indicate the relative high and low of the impurity concentration. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

In addition, the n-type impurity is a so-called donor, and the p-type impurity is a so-called acceptor. In this specification, "impurity" is a term used to refer to either a donor or an acceptor or both.

The impurity concentration in a semiconductor device can be measured by, for example, secondary ion mass spectrometry (SIMS). In addition, the relative high and low of the impurity concentration in the semiconductor device can be determined from, for example, the high and low of the carrier concentration obtained by scanning capacitance microscopy (SCM). In addition, the distance such as the width or depth of an impurity region in the semiconductor device can be calculated by, for example, SIMS. In addition, the distance such as the width or depth of an impurity region in the semiconductor device can be calculated from, for example, an SCM image.

The depth of a trench, the thickness of an insulating layer, and the like of a semiconductor device can be measured, for example, on an image of a scanning electron microscope (SEM) or an image of a transmission electron microscope (TEM).

The electrical resistivity of a member of a semiconductor device can be determined, for example, as an inherent value of the material after identifying the material of the member.

For example, the electrical resistance of a member of a semiconductor device can be determined by direct measurement using a probe needle. In addition, the electrical resistance of the member can be calculated, for example, by identifying the material of the member and the shape of the member itself and performing a calculation using the electrical resistivity of the identified material and the identified shape.

Material identification can be performed, for example, by energy dispersive X-ray spectroscopy (EDX). In addition, shape identification can be performed, for example, on an SEM image or a TEM image.

### First Embodiment

A semiconductor device according to a first embodiment includes: a semiconductor layer having a first face and a second face opposite to the first face and including a first trench provided on a first face side, a gate trench provided on the first face side and surrounding the first trench, a first semiconductor region of a first conductive type, a second semiconductor region of a second conductive type provided between the first semiconductor region and the first face, and a third semiconductor region of the first conductive type provided between the second semiconductor region and the first face; a first field plate electrode provided in the first trench; a first field plate insulating layer provided between the first field plate electrode and the semiconductor layer; a gate electrode provided in the gate trench; a gate insulating layer provided between the gate electrode and the semiconductor layer; a first electrode provided on a side of the first face of the semiconductor layer and electrically connected to the third semiconductor region and the first field plate electrode; a second electrode provided on a side of the second face of the semiconductor layer and electrically connected to the first semiconductor region; and a connection portion provided between the first electrode and the first field plate electrode, electrically connected to the first electrode and the first field plate electrode, and having an electrical resistance higher than an electrical resistance of the first field plate electrode.

The semiconductor device according to the first embodiment is a vertical transistor in which a gate electrode and a field plate electrode are buried in a trench. The semiconductor device according to the first embodiment is a vertical power metal oxide semiconductor field effect transistor (MOSFET). The semiconductor device according to the first embodiment is a MOSFET 100.

The trench in this specification is a groove-shaped or concave structure that the semiconductor layer itself has, and a structure other than the semiconductor layer can be provided thereinside. The trench is a part of the semiconductor layer.

Hereinafter, a case where the first conductive type is n-type and the second conductive type is p-type will be described as an example. A case of an n-channel MOSFET using electrons as carriers will be described as an example.

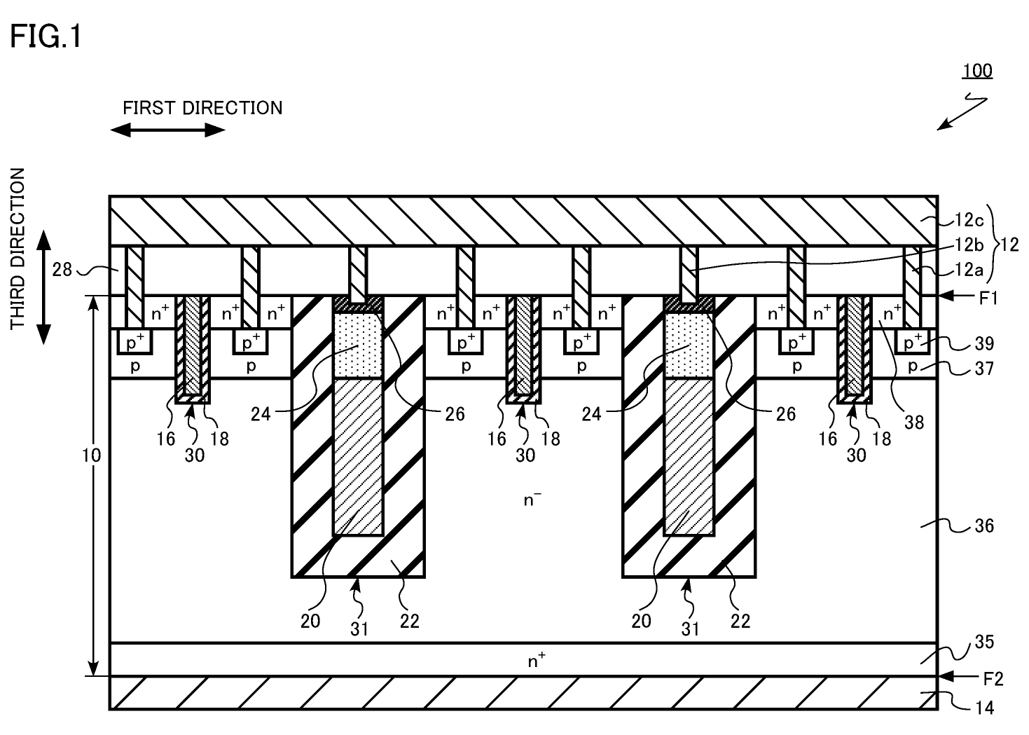

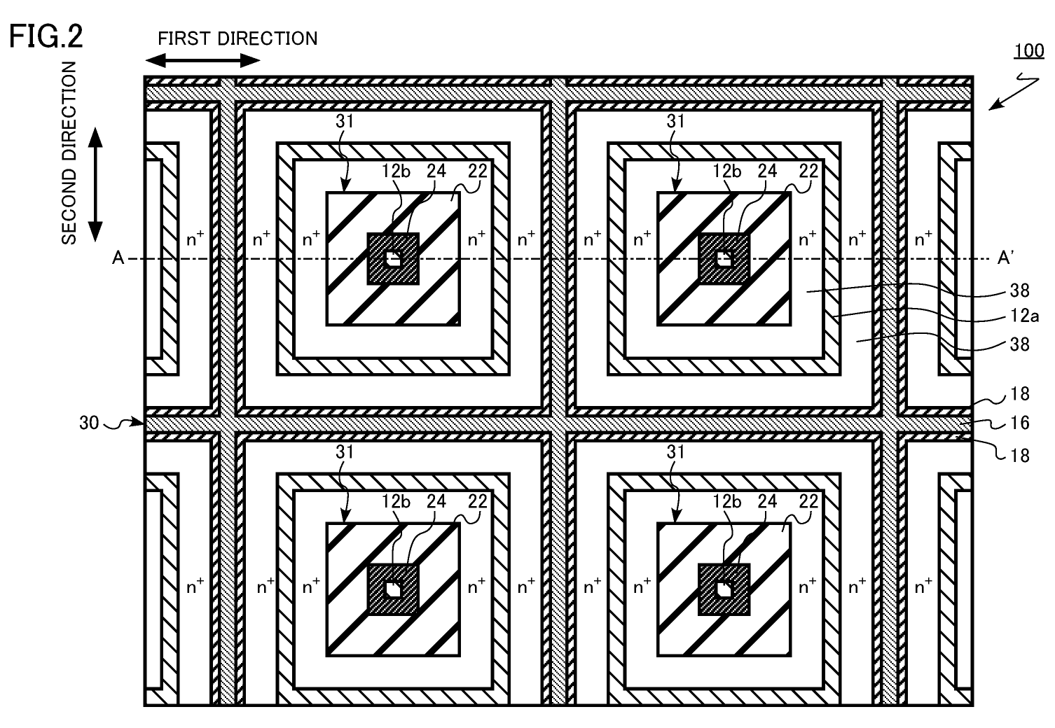

FIG. 1 is a schematic cross-sectional view of the semiconductor device according to the first embodiment. FIG. 2 is a schematic plan view of the semiconductor device according to the first embodiment. FIG. 2 is a plan view of a first face (F1 in FIG. 1) in FIG. 1. FIG. 1 is a cross-sectional view taken along the line AA' of FIG. 2.

The MOSFET 100 includes a silicon layer 10 (semiconductor layer), a source electrode 12 (first electrode), a drain electrode 14 (second electrode), a gate electrode 16, a gate insulating layer 18, a first field plate electrode 20, a first field plate insulating layer 22, a connection portion 24, a contact portion 26, and an interlayer insulating layer 28 (first insulating layer).

The source electrode 12 includes a first contact plug portion 12a, a second contact plug portion 12b, and a surface layer portion 12c.

The silicon layer 10 includes a gate trench 30, a first field plate trench 31 (first trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The silicon layer 10 is provided between the source electrode 12 and the drain electrode 14. The silicon layer 10 has a first face ("F1" in FIG. 1) and a second face ("F2" in FIG. 1). The second face F2 is opposite to the first face F1.

The first direction and the second direction are directions parallel to the first face F1. The second direction is a direction crossing the first direction. The second direction is, for example, a direction perpendicular to the first direction. In addition, the third direction is a direction perpendicular to the first face F1. The third direction is a direction perpendicular to the first direction and the second direction.

Hereinafter, "depth" means a depth with respect to the first face F1. That is, "depth" means a distance in the third direction with respect to the first face F1.

The silicon layer 10 is single crystal silicon (Si). The surface of the silicon layer 10 is a face inclined at an angle equal to or more than 0° and equal to or less than 8° with respect to the (100)-face, for example.

The n⁺-type drain region 35 is provided in the silicon layer 10. The drain region 35 contains n-type impurities. The n-type impurity is, for example, phosphorus (P) or arsenic (As). The n-type impurity concentration in the drain region 35 is, for example, equal to or more than 1 × 10¹⁸ cm⁻³ and equal to or less than 1 × 10²¹ cm⁻³.

The n⁻-type drift region 36 is provided in the silicon layer 10. The drift region 36 is provided between the drain region 35 and the first face F1. The drift region 36 is provided on the drain region 35.

The drift region 36 contains n-type impurities. The n-type impurity is, for example, phosphorus (P) or arsenic (As). The n-type impurity concentration in the drift region 36 is, for example, equal to or more than 1 × 10¹⁵ cm⁻³ and equal to or less than 1 × 10¹⁸ cm⁻³. The drift region 36 is, for example, an epitaxial growth layer formed on the n⁺-type drain region 35 by epitaxial growth.

The thickness of the drift region 36 in the third direction is, for example, equal to or more than 7 μm and equal to or less than 15 μm.

The p-type body region 37 is provided in the silicon layer 10. The body region 37 is provided between the drift region 36 and the first face F1.

The body region 37 is provided between two first field plate trenches 31 adjacent to each other. The body region 37 is provided between the gate trench 30 and the first field plate trench 31.

When the MOSFET 100 is turned on, a channel is formed in the body region 37 in contact with the gate insulating layer 18.

The body region 37 contains p-type impurities. The p-type impurity is, for example, boron (B). The p-type impurity concentration in the body region 37 is equal to or more than 1 × 10¹⁶ cm⁻³ and equal to or less than 1 × 10¹⁸ cm⁻³, for example.

The n⁺-type source region 38 is provided in the silicon layer 10. The source region 38 is provided between the body region 37 and the first face F1.

The source region 38 is provided between two first field plate trenches 31 adjacent to each other. The source region 38 is provided between the gate trench 30 and the first field plate trench 31.

The source region 38 contains n-type impurities. The n-type impurity is, for example, phosphorus (P) or arsenic (As). The n-type impurity concentration in the source region 38 is, for example, equal to or more than 1 × 10¹⁹ cm⁻³ and equal to or less than 1 × 10²¹ cm⁻³.

The p⁺-type contact region 39 is provided in the silicon layer 10. The contact region 39 is provided between the body region 37 and the first face F1.

The contact region 39 contains p-type impurities. The p-type impurity is, for example, boron (B). The p-type impurity concentration in the contact region 39 is higher than the p-type impurity concentration in the body region 37. The p-type impurity concentration in the contact region 39 is, for example, equal to or more than 1 × 10¹⁹ cm⁻³ and equal to or less than 1 × 10²¹ cm⁻³.

The gate trench 30 is provided in the silicon layer 10. The gate trench 30 is provided on the first face F1 side of the silicon layer 10. The gate trench 30 is a groove formed in the silicon layer 10.

The gate trench 30 surrounds the first field plate trench 31. The gate trench 30 has a mesh shape on the first face F1.

The gate electrode 16 is provided in the gate trench 30. A gate insulating layer 18 is provided between the gate electrode 16 and the silicon layer 10.

The gate electrode 16 is a conductor. The gate electrode 16 is, for example, a metal, a metal nitride, a metal carbide, or a metal semiconductor compound.

The gate electrode 16 contains, for example, polycrystalline silicon. The gate electrode 16 is, for example, a polycrystalline silicon containing n-type impurities or p-type impurities. The gate electrode 16 is, for example, an n-type polycrystalline silicon or a p-type polycrystalline silicon.

The first field plate trench 31 is provided in the silicon layer 10. The first field plate trench 31 is provided on the first face F1 side of the silicon layer 10. The first field plate trench 31 is a groove formed in the silicon layer 10.

As shown in FIG. 2, the first field plate trench 31 is provided in a dot pattern on the first face F1. The first field plate trench 31 is surrounded by the gate trench 30. The first field plate trench 31 is deeper than the gate trench 30.

The first field plate electrode 20 is provided in the first field plate trench 31.

The first field plate electrode 20 is electrically connected to the source electrode 12.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The impurity concentration in the first field plate electrode 20 is, for example, equal to or more than 1 × 10¹⁹ cm⁻³ and equal to or less than 1 × 10²² cm⁻³. When the first field plate electrode 20 is an n-type polycrystalline silicon, the n-type impurity concentration in the first field plate electrode 20 is, for example, equal to or more than 1 × 10¹⁹ cm⁻³ and equal to or less than 1 × 10²² cm⁻³. When the first field plate electrode 20 is a p-type polycrystalline silicon, the p-type impurity concentration in the first field plate electrode 20 is, for example, equal to or more than 1 × 10¹⁹ cm⁻³ and equal to or less than 1 × 10²² cm⁻³.

The first field plate insulating layer 22 is provided between the first field plate electrode 20 and the silicon layer 10. The first field plate insulating layer 22 is provided between the first field plate electrode 20 and the drift region 36. The first field plate insulating layer 22 is, for example, a silicon oxide.

The connection portion 24 is provided between the source electrode 12 and the first field plate electrode 20. The connection portion 24 electrically connects the source electrode 12 and the first field plate electrode 20 to each other. The connection portion 24 is provided in the first field plate trench 31.

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The connection portion 24 contains polycrystalline silicon. The connection portion 24 is, for example, a polycrystalline silicon containing impurities. The connection portion 24 is, for example, a polycrystalline silicon containing n-type impurities or p-type impurities. The connection portion 24 is, for example, an n-type polycrystalline silicon or a p-type polycrystalline silicon.

The impurity concentration of the polycrystalline silicon in the connection portion 24 is lower than the impurity concentration of the polycrystalline silicon in the first field plate electrode 20. The impurity concentration of the polycrystalline silicon in the connection portion 24 is, for example, equal to or less than 1/100 of the impurity concentration of the polycrystalline silicon in the first field plate electrode 20.

The impurity concentration of the polycrystalline silicon in the connection portion 24 is, for example, equal to or more than 1 × 10¹¹ cm⁻³ and equal to or less than 1 × 10¹⁷ cm⁻³. When the connection portion 24 is an n-type polycrystalline silicon, the n-type impurity concentration in the connection portion 24 is, for example, equal to or more than 1 × 10¹¹ cm⁻³ and equal to or less than 1 × 10¹⁷ cm⁻³. When the connection portion 24 is a p-type polycrystalline silicon, the p-type impurity concentration in the connection portion 24 is, for example, equal to or more than 1 × 10¹¹ cm⁻³ and equal to or less than 1 × 10¹⁷ cm⁻³.

The contact portion 26 is provided between the source electrode 12 and the connection portion 24. The contact portion 26 electrically connects the source electrode 12 and the connection portion 24 to each other.

The contact portion 26 is in contact with the source electrode 12. The contact portion 26 is in contact with the second contact plug portion 12b of the source electrode 12. The contact portion 26 is in contact with the connection portion 24. The contact portion 26 is provided in the first field plate trench 31.

The contact portion 26 contains polycrystalline silicon. The contact portion 26 is, for example, a polycrystalline silicon containing impurities. The contact portion 26 is, for example, a polycrystalline silicon containing n-type impurities or p-type impurities. The contact portion 26 is, for example, an n-type polycrystalline silicon or a p-type polycrystalline silicon.

The impurity concentration of the polycrystalline silicon in the contact portion 26 is higher than the impurity concentration of the polycrystalline silicon in the connection portion 24. The impurity concentration of the polycrystalline silicon in the contact portion 26 is, for example, equal to or more than 100 times and equal to or less than 1,000,000 times the impurity concentration of the polycrystalline silicon in the connection portion 24.

The impurity concentration of the polycrystalline silicon in the contact portion 26 is higher than the impurity concentration of the polycrystalline silicon in the first field plate electrode 20, for example.

The impurity concentration of the polycrystalline silicon in the contact portion 26 is, for example, equal to or more than 1 × 10²⁰ cm⁻³ and equal to or less than 1 × 10²² cm⁻³. When the contact portion 26 is an n-type polycrystalline silicon, the n-type impurity concentration in the contact portion 26 is, for example, equal to or more than 1 × 10²⁰ cm⁻³ and equal to or less than 1 × 10²² cm⁻³. When the contact portion 26 is a p-type polycrystalline silicon, the p-type impurity concentration in the connection portion 24 is, for example, equal to or more than 1 × 10²⁰ cm⁻³ and equal to or less than 1 × 10²² cm⁻³.

By providing the contact portion 26, for example, the contact resistance of the second contact plug portion 12b can be reduced.

The interlayer insulating layer 28 is provided between the source electrode 12 and the silicon layer 10. The interlayer insulating layer 28 is provided between the source electrode 12 and the first field plate electrode 20. The interlayer insulating layer 28 is provided between the source electrode 12 and the gate electrode 16.

The interlayer insulating layer 28 is an insulator. The interlayer insulating layer 28 is, for example, a silicon oxide.

The source electrode 12 is provided on the first face F1 side of the silicon layer 10. The source electrode 12 is provided on the first face F1 of the silicon layer 10.

The source electrode 12 is electrically connected to the source region 38 and the contact region 39. The source electrode 12 is electrically connected to the first field plate electrode 20.

The source electrode 12 includes the first contact plug portion 12a, the second contact plug portion 12b, and the surface layer portion 12c.

The first contact plug portion 12a is provided, for example, between the silicon layer 10 and the surface layer portion 12c. The first contact plug portion 12a is in contact with, for example, the silicon layer 10. The first contact plug portion 12a is in contact with, for example, the contact region 39. For example, the bottom surface of the first contact plug portion 12a is in contact with the contact region 39.

The first contact plug portion 12a is in contact with, for example, the source region 38. For example, the side surface of the first contact plug portion 12a is in contact with the source region 38.

A part of the first contact plug portion 12a fills, for example, a recess provided in the silicon layer 10. A part of the first contact plug portion 12a is provided, for example, in a recess provided in the silicon layer 10.

The second contact plug portion 12b is provided, for example, between the contact portion 26 and the surface layer portion 12c. The second contact plug portion 12b is in contact with, for example, the contact portion 26.

A part of the second contact plug portion 12b fills, for example, a recess provided in the contact portion 26. A part of the second contact plug portion 12b is provided, for example, in a recess provided in the contact portion 26.

The surface layer portion 12c is provided on a plurality of first contact plug portions 12a and a plurality of second contact plug portions 12b. The surface layer portion 12c electrically connects the plurality of first contact plug portions 12a and the plurality of second contact plug portions 12b to each other.

The surface layer portion 12c is a region to which, for example, bonding wires are connected when the MOSFET 100 is mounted.

The source electrode 12 is a conductor. The source electrode 12 is, for example, a metal. The first contact plug portion 12a, the second contact plug portion 12b, and the surface layer portion 12c may be formed of the same material or different materials.

The first contact plug portion 12a and the second contact plug portion 12b have a stacked structure of, for example, titanium, titanium nitride, and tungsten. The surface layer portion 12c has a stacked structure of, for example, titanium nitride and aluminum.

The drain electrode 14 is provided on the second face F2 side of the silicon layer 10. The drain electrode 14 is provided on the second face F2 of the silicon layer 10. The drain electrode 14 is electrically connected to the drain region 35. The drain electrode 14 is in contact with the drain region 35. The drain electrode 14 is electrically connected to the drift region 36.

The drain electrode 14 is a conductor. The drain electrode 14 is, for example, a metal. The drain electrode 14 has a stacked structure of materials selected from a group consisting of, for example, titanium, aluminum, nickel, copper, silver, and gold.

Hereinafter, the function and effect of the semiconductor device according to the first embodiment will be described.

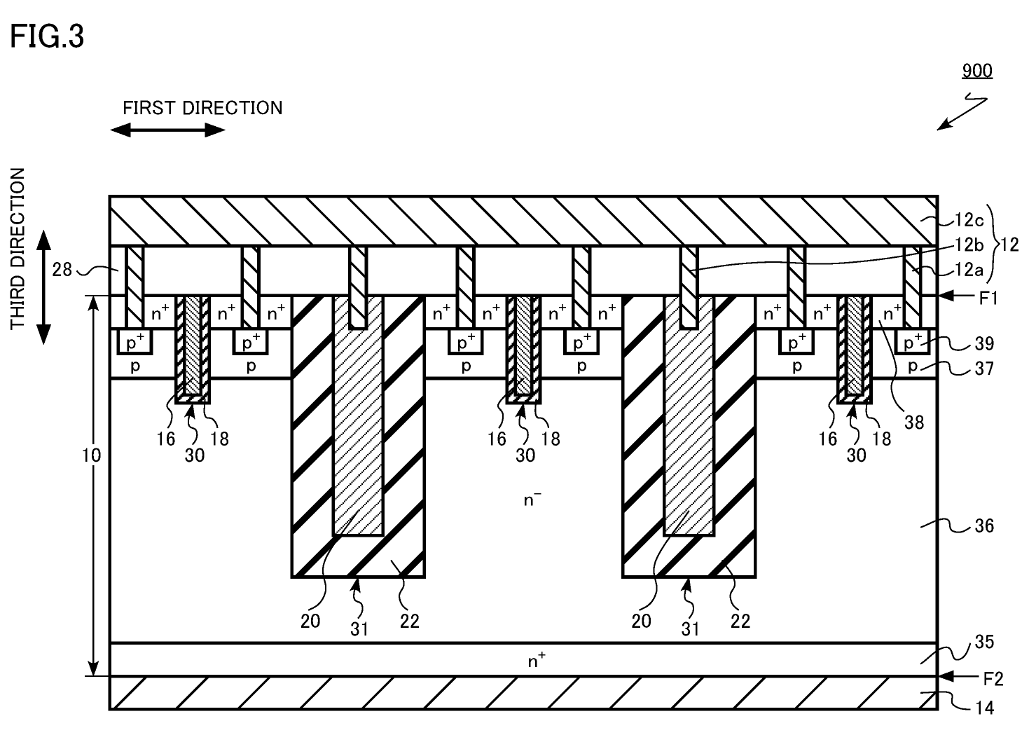

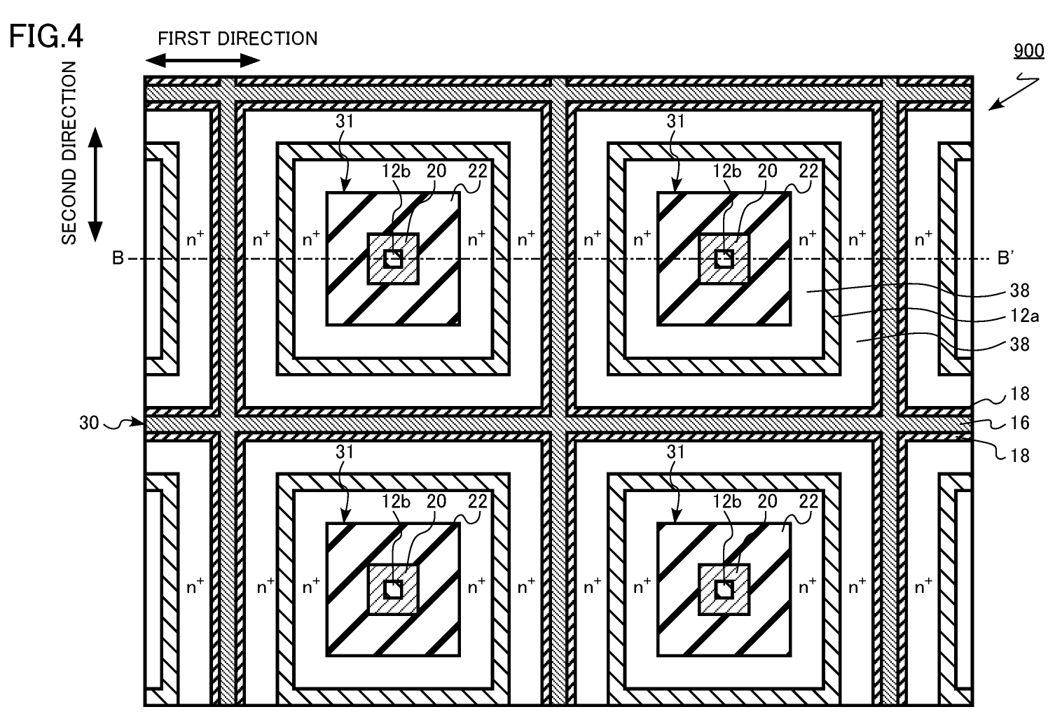

FIG. 3 is a schematic cross-sectional view of a semiconductor device according to a comparative example. FIG. 4 is a schematic plan view of the semiconductor device according to the comparative example. FIG. 4 is a plan view of a first face (F1 in FIG. 3) in FIG. 3. FIG. 3 is a cross-sectional view taken along the line BB' of FIG. 4.

FIG. 3 is a diagram corresponding to FIG. 1 in the first embodiment. FIG. 4 is a diagram corresponding to FIG. 2 in the first embodiment.

The semiconductor device according to the comparative example is a vertical transistor in which a gate electrode and a field plate electrode are buried in a trench. The semiconductor device according to the comparative example is a vertical power MOSFET. The semiconductor device according to the comparative example is a MOSFET 900.

The MOSFET 900 according to the comparative example is different from the MOSFET 100 according to the first embodiment in that the MOSFET 900 does not include the connection portion 24 and the contact portion 26.

As shown in FIG. 3, in the MOSFET 900, the source electrode 12 is in contact with the first field plate electrode 20. The second contact plug portion 12b of the source electrode 12 is in contact with the first field plate electrode 20.

In the MOSFET 900, the first field plate electrode 20 electrically connected to the source electrode 12 is provided in the first field plate trench 31. By changing the electric field distribution in the drift region 36 using the first field plate electrode 20, it is possible to increase the impurity concentration in the drift region 36 while maintaining the breakdown voltage of the MOSFET 900, for example. Therefore, according to the MOSFET 900, it is possible to reduce the on-resistance while maintaining the breakdown voltage.

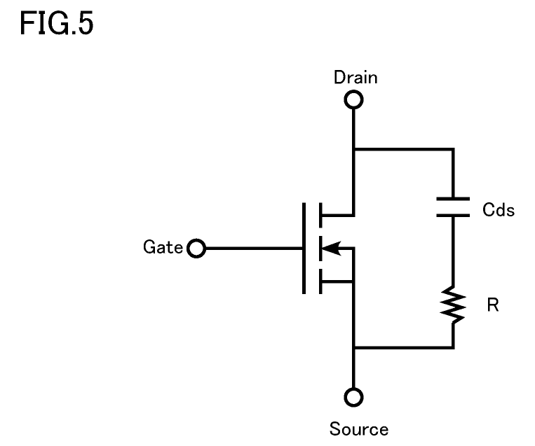

FIG. 5 is an explanatory diagram of the function and effect of the semiconductor device according to the first embodiment. FIG. 5 is an equivalent circuit diagram of the MOSFET 900 according to the comparative example.

As shown in FIG. 5, when the field plate electrode is electrically connected to the source electrode of the vertical transistor, a snubber circuit in which the electrical resistance (R in FIG. 5) between the source electrode and the field plate electrode and the capacitance (Cds in FIG. 5) between the field plate electrode and the semiconductor layer are connected in series is formed between the source electrode and drain electrode. By providing the snubber circuit, it is possible to suppress ringing during the OFF operation of the MOSFET.

If the electrical resistance R of the snubber circuit is low, ringing during the OFF operation cannot be suppressed. For this reason, ringing may occur in the MOSFET. When ringing occurs in the MOSFET, for example, the current flowing through the electronic circuit including the MOSFET increases, causing a problem in that the power consumption of the electronic circuit increases.

In the MOSFET 900 according to the comparative example, the source electrode 12 and the first field plate electrode 20 are electrically connected to each other directly above the first field plate electrode 20. Therefore, the path between the source electrode 12 and the first field plate electrode 20 is shortened, and the electrical resistance R between the source electrode 12 and the first field plate electrode 20 is reduced. As a result, ringing may occur during the OFF operation of the MOSFET 900.

The MOSFET 100 according to the first embodiment includes the connection portion 24 between the source electrode 12 and the first field plate electrode 20, the connection portion 24 having a higher resistance than the first field plate electrode 20. Therefore, the electrical resistance R between the source electrode 12 and the first field plate electrode 20 becomes higher than that in the MOSFET 900 according to the comparative example. As a result, the occurrence of ringing during the OFF operation of the MOSFET 100 is suppressed.

From the viewpoint of suppressing ringing, the electrical resistance of the connection portion 24 is preferably equal to or more than 100 times, more preferably equal to or more than 1000 times the electrical resistance of the first field plate electrode 20.

From the viewpoint of suppressing ringing, the impurity concentration of the polycrystalline silicon in the connection portion 24 is preferably equal to or less than 1/100, more preferably equal to or less than 1/1000 of the impurity concentration of the polycrystalline silicon in the first field plate electrode 20.

From the viewpoint of reducing the contact resistance of the second contact plug portion 12b, the impurity concentration of the polycrystalline silicon in the contact portion 26 is preferably equal to or more than 100 times, more preferably equal to or more than 1,000 times, and even more preferably equal to or more than 10,000 times the impurity concentration of the polycrystalline silicon in the connection portion 24.

From the viewpoint of reducing the contact resistance of the second contact plug portion 12b, it is preferable that the impurity concentration of the polycrystalline silicon in the contact portion 26 is higher than the impurity concentration of the polycrystalline silicon in the first field plate electrode 20.

### Modification Example

A semiconductor device according to a modification example of the first embodiment is different from the semiconductor device according to the first embodiment in that the semiconductor device according to the modification example of the first embodiment does not include a contact portion.

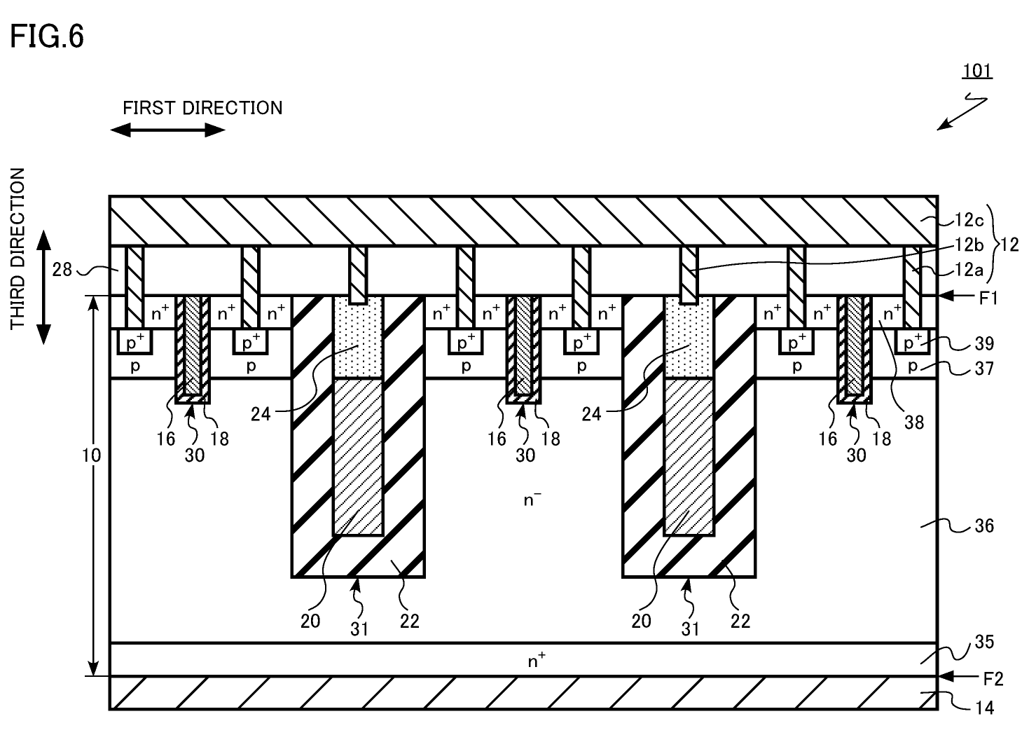

FIG. 6 is a schematic cross-sectional view of the semiconductor device according to the modification example of the first embodiment. FIG. 6 is a diagram corresponding to FIG. 1 in the first embodiment.

The semiconductor device according to the modification example of the first embodiment is a MOSFET 101.

The MOSFET 101 according to the modification example of the first embodiment is different from the MOSFET 100 according to the first embodiment in that the MOSFET 101 does not include the contact portion 26.

In the MOSFET 101 according to the modification example of the first embodiment as well, the occurrence of ringing during the OFF operation is suppressed as in the MOSFET 100 according to the first embodiment.

As described above, according to the first embodiment and its modification example, it is possible to realize a MOSFET capable of suppressing ringing.

### Second Embodiment

A semiconductor device according to a second embodiment is different from the semiconductor device according to the first embodiment in that the width of the connection portion in the first direction parallel to the first face is smaller than the width of the first field plate electrode in the first direction. Hereinafter, the description of a part of the content overlapping the first embodiment may be omitted.

The semiconductor device according to the second embodiment is a vertical transistor in which a gate electrode and a field plate electrode are buried in a trench. The semiconductor device according to the second embodiment is a vertical power MOSFET. The semiconductor device according to the second embodiment is a MOSFET 200.

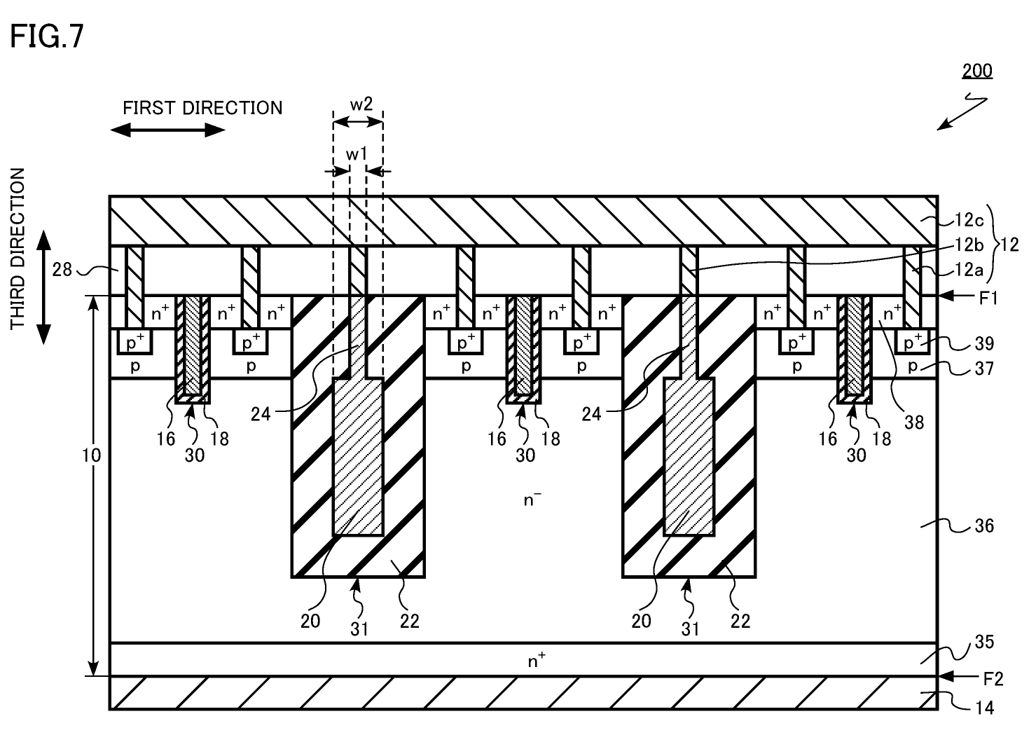

FIG. 7 is a schematic cross-sectional view of the semiconductor device according to the second embodiment. FIG. 7 is a diagram corresponding to FIG. 1 in the first embodiment.

The MOSFET 200 includes a silicon layer 10 (semiconductor layer), a source electrode 12 (first electrode), a drain electrode 14 (second electrode), a gate electrode 16, a gate insulating layer 18, a first field plate electrode 20, a first field plate insulating layer 22, a connection portion 24, and an interlayer insulating layer 28 (first insulating layer).

The source electrode 12 includes a first contact plug portion 12a, a second contact plug portion 12b, and a surface layer portion 12c.

The silicon layer 10 includes a gate trench 30, a first field plate trench 31 (first trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The width (w1 in FIG. 7) of the connection portion 24 in the first direction parallel to the first face F1 is smaller than the width (w2 in FIG. 7) of the first field plate electrode 20 in the first direction. The width w1 of the connection portion 24 in the first direction parallel to the first face F1 is, for example, equal to or more than 1/100 and equal to or less than 1/2 of the width w2 of the first field plate electrode 20 in the first direction.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The connection portion 24 is provided in the first field plate trench 31.

The connection portion 24 contains polycrystalline silicon. The connection portion 24 is, for example, a polycrystalline silicon containing impurities. The connection portion 24 is, for example, a polycrystalline silicon containing n-type impurities or p-type impurities. The connection portion 24 is, for example, an n-type polycrystalline silicon or a p-type polycrystalline silicon.

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The impurity concentration of the polycrystalline silicon in the connection portion 24 is, for example, substantially equal to the impurity concentration of the polycrystalline silicon in the first field plate electrode 20. The impurity concentration of the polycrystalline silicon in the connection portion 24 is lower than the impurity concentration of the polycrystalline silicon in the first field plate electrode 20, for example. The impurity concentration of the polycrystalline silicon in the connection portion 24 is, for example, equal to or less than 1/100 of the impurity concentration of the polycrystalline silicon in the first field plate electrode 20.

In the MOSFET 200 according to the second embodiment, the width w1 of the connection portion 24 is made smaller than the width w2 of the first field plate electrode 20, so that the electrical resistance R between the source electrode 12 and the first field plate electrode 20 is increased. As a result, the occurrence of ringing during the OFF operation of the MOSFET 200 is suppressed.

From the viewpoint of suppressing ringing, the width w1 of the connection portion 24 is preferably equal to or less than 1/2, more preferably equal to or less than 1/3, and even more preferably equal to or less than 1/4 of the width w2 of the first field plate electrode 20.

### Modification Example

A semiconductor device according to a modification example of the second embodiment is different from the semiconductor device according to the second embodiment in that the width of an upper portion of the first trench in the first direction is smaller than the width of a lower portion of the first trench in the first direction.

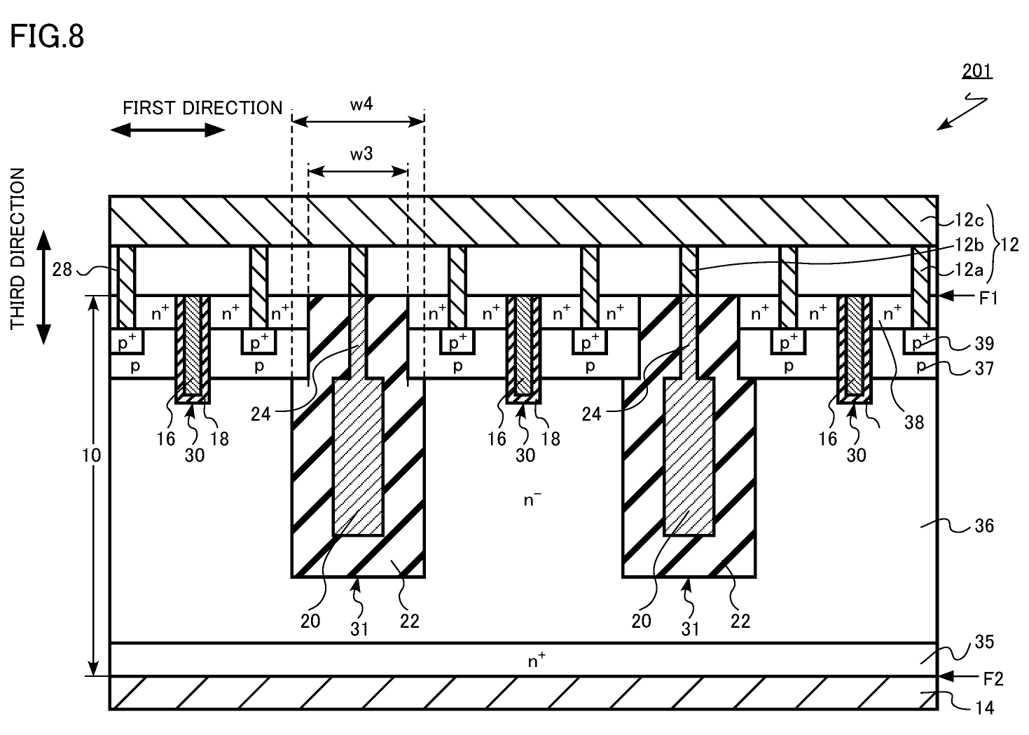

FIG. 8 is a schematic cross-sectional view of the semiconductor device according to the modification example of the second embodiment. FIG. 8 is a diagram corresponding to FIG. 7 in the second embodiment.

The semiconductor device according to the modification example of the second embodiment is a MOSFET 201.

In the MOSFET 201 according to the modification example of the second embodiment, the width (w3 in FIG. 8) of the upper portion of the first field plate trench 31 in the first direction is smaller than the width (w4 in FIG. 8) of the lower portion of the first field plate trench 31 in the first direction. The width w3 of the upper portion of the first field plate trench 31 in the first direction is, for example, equal to or more than 10% and equal to or less than 80% of the width w4 of the lower portion of the first field plate trench 31 in the first direction.

The MOSFET 201 can be manufactured, for example, by forming the first field plate trench 31 in the silicon layer 10 so that the width of the upper portion is smaller than the width of the lower portion.

In the MOSFET 201 according to the modification example of the second embodiment as well, the occurrence of ringing during the OFF operation is suppressed as in the MOSFET 200 according to the second embodiment. In addition, in the MOSFET 201, the distance between the gate trench 30 and the first field plate trench 31 on the first face F1 is larger than that in the MOSFET 200. Therefore, for example, the first contact plug portion 12a can be easily formed.

As described above, according to the second embodiment and its modification example, it is possible to realize a MOSFET capable of suppressing ringing.

### Third Embodiment

A semiconductor device according to a third embodiment is different from the semiconductor device according to the first embodiment in that the material of the connection portion is different from the material of the first field plate electrode. Hereinafter, the description of a part of the content overlapping the first embodiment may be omitted.

The semiconductor device according to the third embodiment is a vertical transistor in which a gate electrode and a field plate electrode are buried in a trench. The semiconductor device according to the third embodiment is a vertical power MOSFET. The semiconductor device according to the third embodiment is a MOSFET 300.

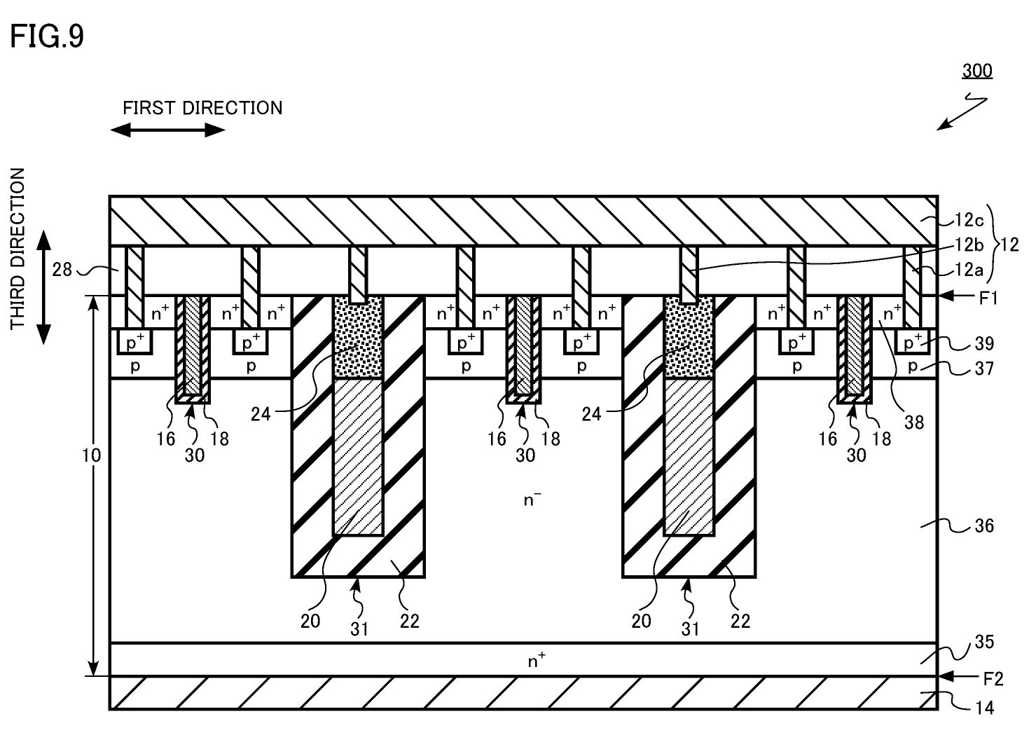

FIG. 9 is a schematic cross-sectional view of the semiconductor device according to the third embodiment. FIG. 9 is a diagram corresponding to FIG. 1 in the first embodiment.

The MOSFET 300 includes a silicon layer 10 (semiconductor layer), a source electrode 12 (first electrode), a drain electrode 14 (second electrode), a gate electrode 16, a gate insulating layer 18, a first field plate electrode 20, a first field plate insulating layer 22, a connection portion 24, and an interlayer insulating layer 28 (first insulating layer).

The source electrode 12 includes a first contact plug portion 12a, a second contact plug portion 12b, and a surface layer portion 12c.

The silicon layer 10 includes a gate trench 30, a first field plate trench 31 (first trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The connection portion 24 is provided in the first field plate trench 31.

The material of the connection portion 24 is different from the material of the first field plate electrode 20. The material of the connection portion 24 is, for example, a material different from polycrystalline silicon. The material of the connection portion 24 is, for example, a silicon nitride or a silicon oxynitride. The material of the connection portion 24 is, for example, a semi-insulating silicon nitride (SinSiN).

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The electrical resistivity of the material of the connection portion 24 is larger than the electrical resistivity of the first field plate electrode 20.

In the MOSFET 300 according to the third embodiment, the electrical resistance R between the source electrode 12 and the first field plate electrode 20 is increased by using, for the material of the connection portion 24, a material having a higher electrical resistivity than the material of the first field plate electrode. As a result, the occurrence of ringing during the OFF operation of the MOSFET 300 is suppressed.

### Modification Example

A semiconductor device according to a modification example of the third embodiment is different from the semiconductor device according to the third embodiment in that the width of the connection portion in the first direction parallel to the first face is smaller than the width of the first field plate electrode in the first direction.

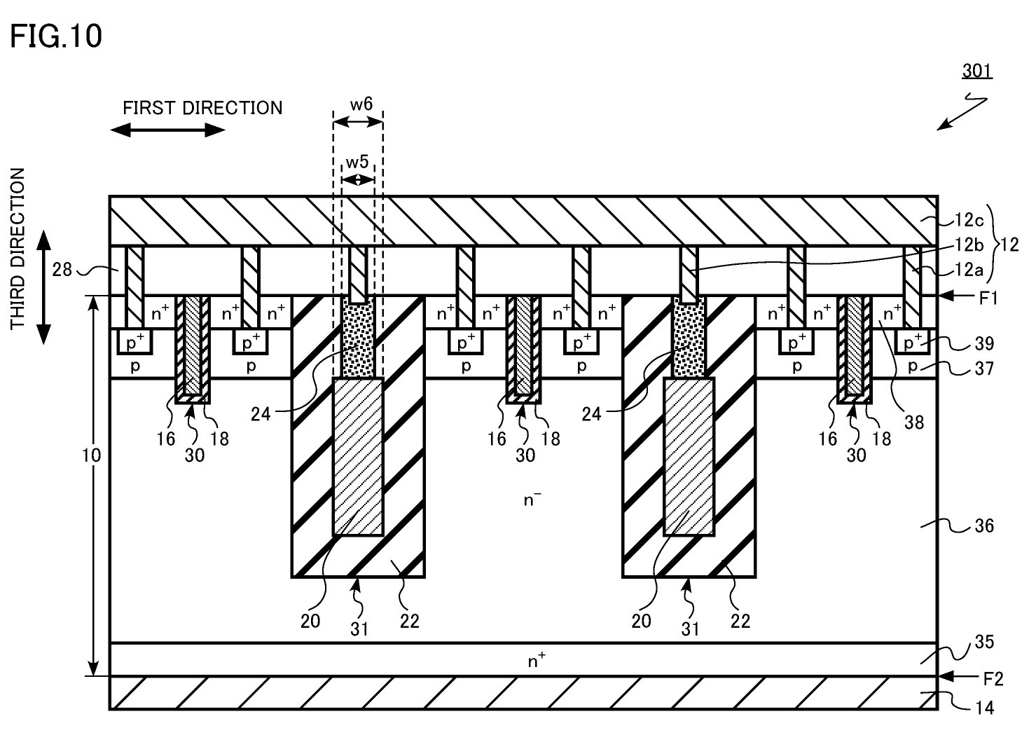

FIG. 10 is a schematic cross-sectional view of the semiconductor device according to the modification example of the third embodiment. FIG. 10 is a diagram corresponding to FIG. 9 in the third embodiment.

The semiconductor device according to the modification example of the third embodiment is a MOSFET 301.

In the MOSFET 301 according to the modification example of the third embodiment, the width (w5 in FIG. 10) of the connection portion 24 in the first direction parallel to the first face F1 is smaller than the width (w6 in FIG. 10) of the first field plate electrode 20 in the first direction.

In the MOSFET 301 according to the modification example of the third embodiment, the width w5 of the connection portion 24 is made smaller than the width w6 of the first field plate electrode 20, so that the electrical resistance R between the source electrode 12 and the first field plate electrode 20 is further increased. As a result, the occurrence of ringing during the OFF operation of the MOSFET 301 is further suppressed.

As described above, according to the third embodiment and its modification example, it is possible to realize a MOSFET capable of suppressing ringing.

### Fourth Embodiment

A semiconductor device according to a fourth embodiment further includes a first insulating layer provided between the first electrode and the semiconductor layer, between the first electrode and the first field plate electrode, and between the first electrode and the gate electrode. Then, the semiconductor device according to the fourth embodiment is different from the semiconductor devices according to the first to third embodiments in that the connection portion is surrounded by the first insulating layer. In other words, the semiconductor device according to the fourth embodiment is different from the semiconductor devices according to the first to third embodiments in that the connection portion is provided outside the first trench. Hereinafter, the description of a part of the content overlapping the first to third embodiments may be omitted.

The semiconductor device according to the fourth embodiment is a vertical transistor in which a gate electrode and a field plate electrode are buried in a trench. The semiconductor device according to the fourth embodiment is a vertical power MOSFET. The semiconductor device according to the fourth embodiment is a MOSFET 400.

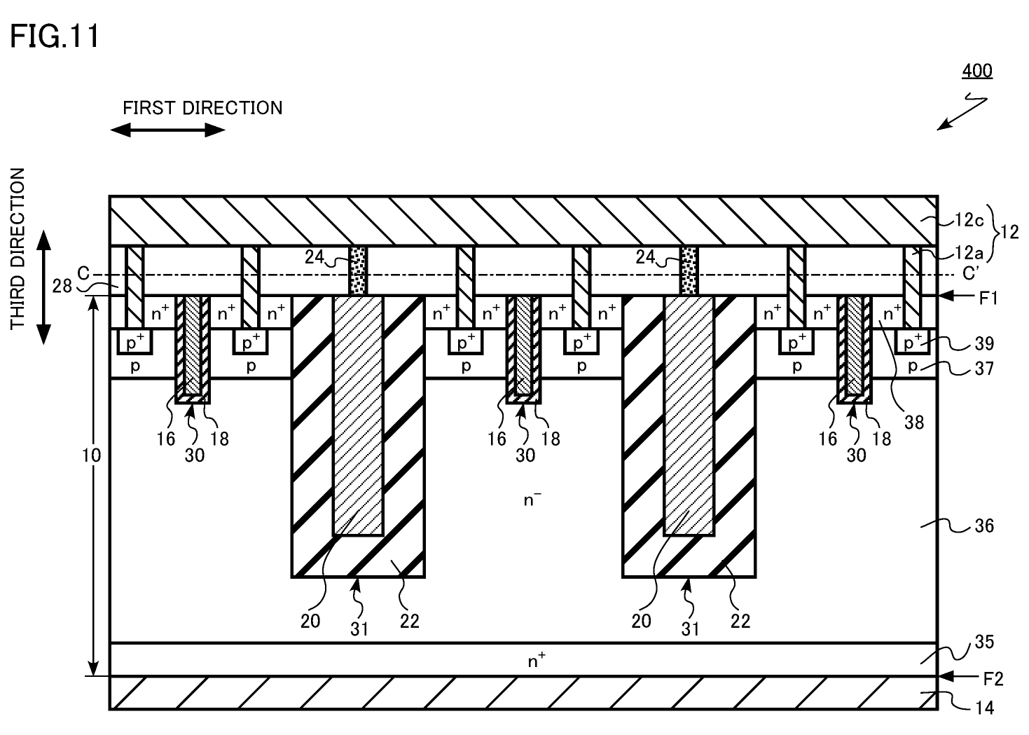

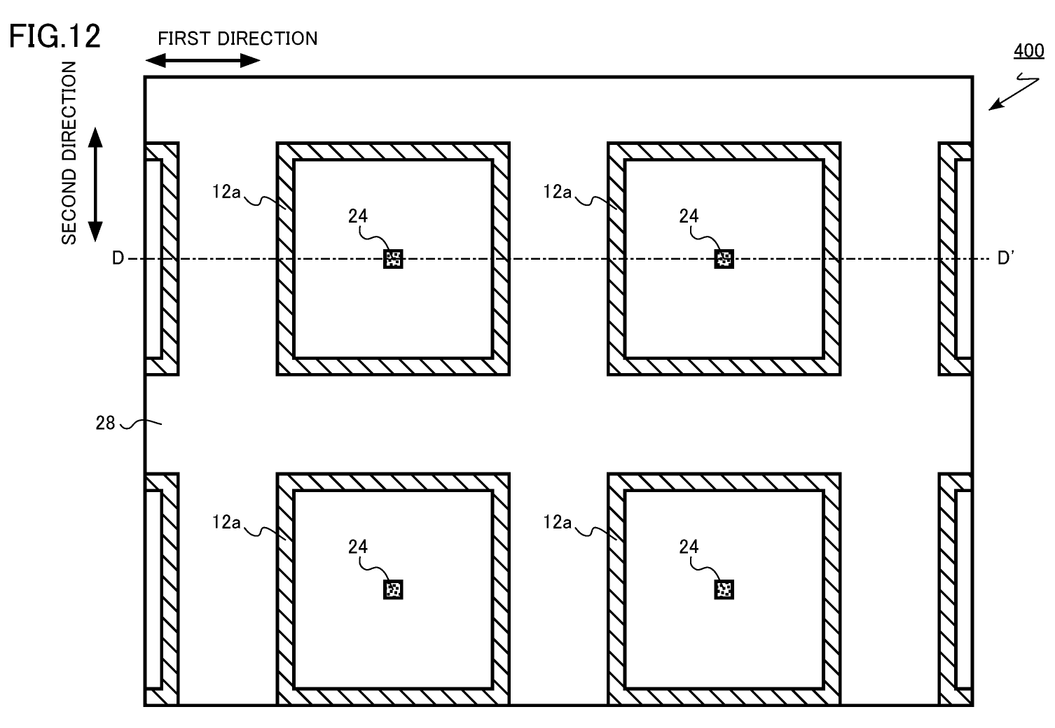

FIG. 11 is a schematic cross-sectional view of the semiconductor device according to the fourth embodiment. FIG. 12 is a schematic cross-sectional view of the semiconductor device according to the fourth embodiment. FIG. 12 is a cross-sectional view taken along the line CC' of FIG. 11. FIG. 11 is a cross-sectional view taken along the line DD' of FIG. 12.

FIG. 11 is a diagram corresponding to FIG. 1 in the first embodiment.

The MOSFET 400 includes a silicon layer 10 (semiconductor layer), a source electrode 12 (first electrode), a drain electrode 14 (second electrode), a gate electrode 16, a gate insulating layer 18, a first field plate electrode 20, a first field plate insulating layer 22, a connection portion 24, and an interlayer insulating layer 28 (first insulating layer).

The source electrode 12 includes a first contact plug portion 12a and a surface layer portion 12c.

The silicon layer 10 includes a gate trench 30, a first field plate trench 31 (first trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The connection portion 24 is provided in the interlayer insulating layer 28. As shown in FIG. 12, the connection portion 24 is surrounded by the interlayer insulating layer 28 in a cross section parallel to the first face F1. The connection portion 24 is provided outside the first field plate trench 31.

The connection portion 24 is provided between the source electrode 12 and the first field plate electrode 20. The connection portion 24 electrically connects the source electrode 12 and the first field plate electrode 20 to each other. The connection portion 24 is in contact with the source electrode 12 and the first field plate electrode 20.

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The material of the connection portion 24 is, for example, a material different from the material of the first field plate electrode 20. The material of the connection portion 24 is, for example, a material different from polycrystalline silicon. The material of the connection portion 24 is, for example, a silicon nitride or a silicon oxynitride. The material of the connection portion 24 is, for example, a semi-insulating silicon nitride (SinSiN).

The electrical resistivity of the material of the connection portion 24 is, for example, larger than the electrical resistivity of the first field plate electrode 20.

The material of the connection portion 24 is, for example, the same material as the material of the first field plate electrode 20. The connection portion 24 contains, for example, polycrystalline silicon. The connection portion 24 is, for example, a polycrystalline silicon containing impurities. The connection portion 24 is, for example, a polycrystalline silicon containing n-type impurities or p-type impurities. The connection portion 24 is, for example, an n-type polycrystalline silicon or a p-type polycrystalline silicon.

The impurity concentration of the polycrystalline silicon in the connection portion 24 is lower than the impurity concentration of the polycrystalline silicon in the first field plate electrode 20. The impurity concentration of the polycrystalline silicon in the connection portion 24 is, for example, equal to or less than 1/100 of the impurity concentration of the polycrystalline silicon in the first field plate electrode 20.

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

In the MOSFET 400 according to the fourth embodiment, the electrical resistance R between the source electrode 12 and the first field plate electrode 20 is increased by providing the high-resistance connection portion 24. As a result, the occurrence of ringing during the OFF operation of the MOSFET 400 is suppressed.

As described above, according to the fourth embodiment, it is possible to realize a MOSFET capable of suppressing ringing.

### Fifth Embodiment

A semiconductor device according to a fifth embodiment is different from the semiconductor device according to the first embodiment in that the connection portion extends in a direction parallel to the first face, a first end of the connection portion is connected to the first field plate electrode, and a second end of the connection portion is connected to the first electrode. Hereinafter, the description of a part of the content overlapping the first to fourth embodiments may be omitted.

The semiconductor device according to the fifth embodiment is a vertical transistor in which a gate electrode and a field plate electrode are buried in a trench. The semiconductor device according to the fifth embodiment is a vertical power MOSFET. The semiconductor device according to the fifth embodiment is a MOSFET 500.

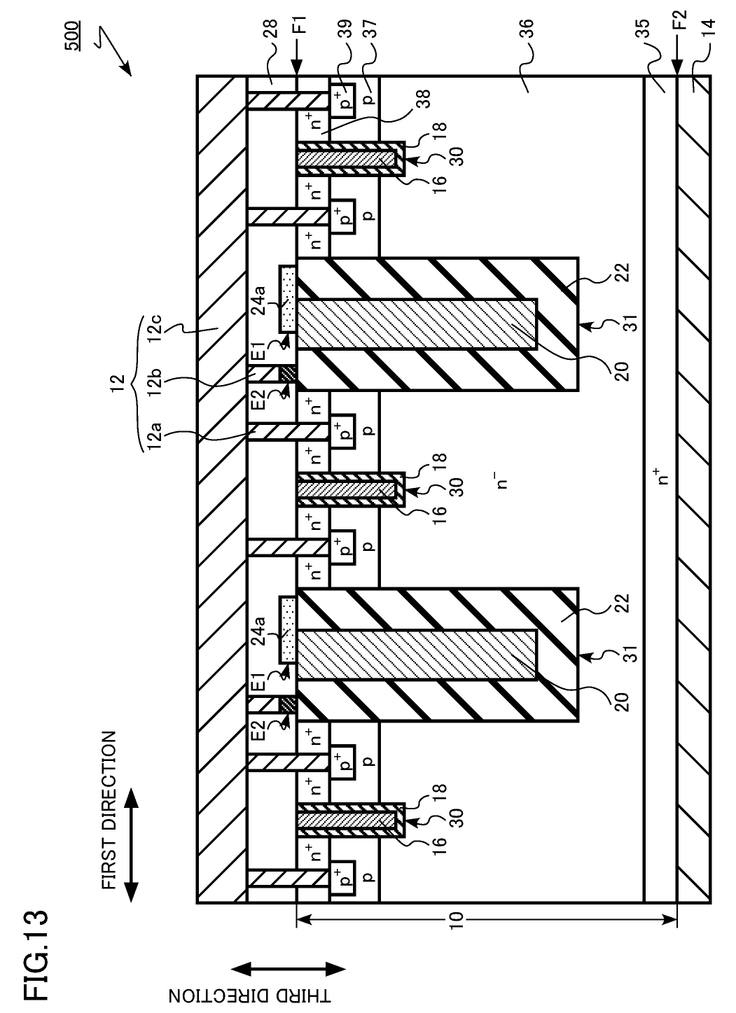

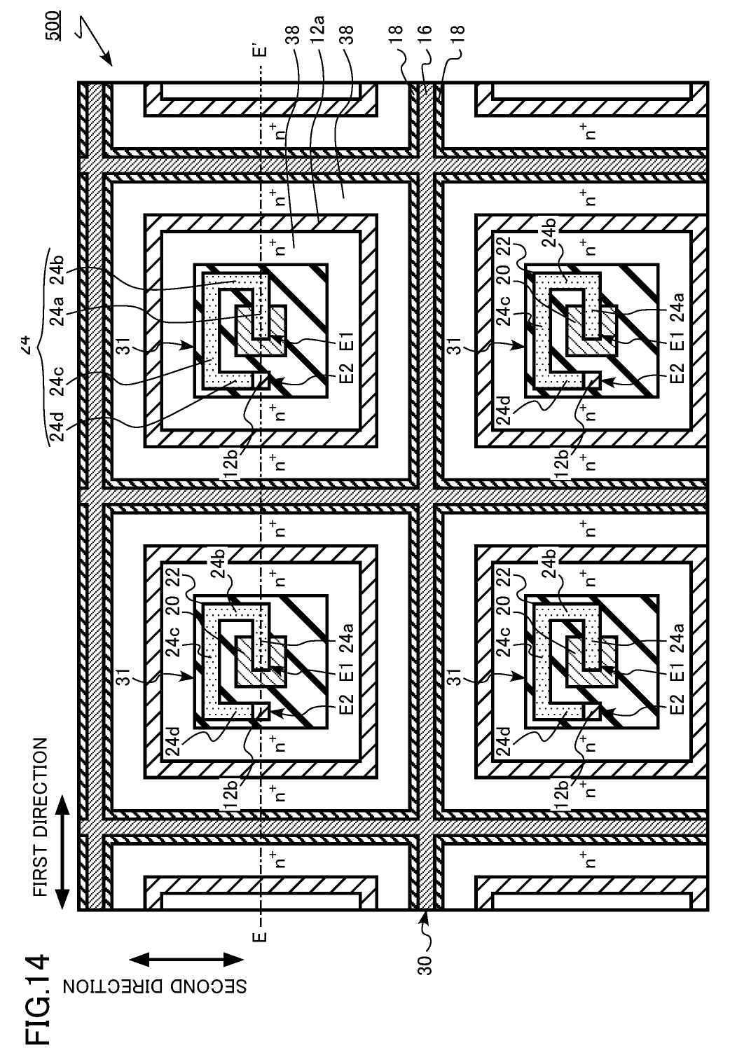

FIG. 13 is a schematic cross-sectional view of the semiconductor device according to the fifth embodiment. FIG. 14 is a schematic top view of the semiconductor device according to the fifth embodiment. FIG. 14 is a diagram showing a state in which the surface layer portion 12c of the source electrode 12 and the interlayer insulating layer 28 are removed. FIG. 13 is a cross-sectional view taken along the line EE' of FIG. 14.

FIG. 13 is a diagram corresponding to FIG. 1 in the first embodiment.

The MOSFET 500 includes a silicon layer 10 (semiconductor layer), a source electrode 12 (first electrode), a drain electrode 14 (second electrode), a gate electrode 16, a gate insulating layer 18, a first field plate electrode 20, a first field plate insulating layer 22, a connection portion 24, and an interlayer insulating layer 28 (first insulating layer).

The source electrode 12 includes a first contact plug portion 12a, a second contact plug portion 12b, and a surface layer portion 12c. The connection portion 24 has a first end E1 and a second end E2. The connection portion 24 includes a first portion 24a, a second portion 24b, a third portion 24c, and a fourth portion 24d.

The silicon layer 10 includes a gate trench 30, a first field plate trench 31 (first trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The impurity concentration in the first field plate electrode 20 is, for example, equal to or more than 1 × 10¹⁹ cm⁻³ and equal to or less than 1 × 10²² cm⁻³. When the first field plate electrode 20 is an n-type polycrystalline silicon, the n-type impurity concentration in the first field plate electrode 20 is, for example, equal to or more than 1 × 10¹⁹ cm⁻³ and equal to or less than 1 × 10²² cm⁻³. When the first field plate electrode 20 is a p-type polycrystalline silicon, the p-type impurity concentration in the first field plate electrode 20 is, for example, equal to or more than 1 × 10¹⁹ cm⁻³ and equal to or less than 1 × 10²² cm⁻³.

The connection portion 24 is provided in the interlayer insulating layer 28. The connection portion 24 is surrounded by the interlayer insulating layer 28 in a cross section parallel to the first face F1. The connection portion 24 is provided outside the first field plate trench 31.

The connection portion 24 is provided between the source electrode 12 and the first field plate electrode 20. The connection portion 24 electrically connects the source electrode 12 and the first field plate electrode 20 to each other.

The connection portion 24 extends in a direction parallel to the first face F1. The first portion 24a and the second portion 24b, the second portion 24b and the third portion 24c, and the third portion 24c and the fourth portion 24d extend in directions crossing each other.

For example, the first portion 24a of the connection portion 24 extends in the first direction. For example, the second portion 24b of the connection portion 24 extends in the second direction. For example, the third portion 24c of the connection portion 24 extends in the first direction. For example, the fourth portion 24d of the connection portion 24 extends in the second direction.

In FIG. 14, the case of the connection portion 24 in which the first portion 24a and the second portion 24b are perpendicular to each other, the second portion 24b and the third portion 24c are perpendicular to each other, and the third portion 24c and the fourth portion 24d are perpendicular to each other is shown as an example. However, the connection portion 24 may have a shape in which the direction gradually changes between the portions.

The connection portion 24 is in contact with the source electrode 12 and the first field plate electrode 20. The first end E1 of the connection portion 24 is connected to the first field plate electrode 20. The first end E1 and the second end E2 opposite thereto of the connection portion 24 are connected to the second contact plug portion 12b of the source electrode 12.

The connection portion 24 contains polycrystalline silicon. The connection portion 24 is, for example, a polycrystalline silicon containing impurities. The connection portion 24 is, for example, a polycrystalline silicon containing n-type impurities or p-type impurities. The connection portion 24 is, for example, an n-type polycrystalline silicon or a p-type polycrystalline silicon.

The impurity concentration of the polycrystalline silicon in the connection portion 24 is lower than the impurity concentration of the polycrystalline silicon in the first field plate electrode 20. The impurity concentration of the polycrystalline silicon in the connection portion 24 is, for example, equal to or less than 1/100 of the impurity concentration of the polycrystalline silicon in the first field plate electrode 20.

The impurity concentration of the polycrystalline silicon in the connection portion 24 is, for example, equal to or more than 1 × 10¹¹ cm⁻³ and equal to or less than 1 × 10¹⁷ cm⁻³. When the connection portion 24 is an n-type polycrystalline silicon, the n-type impurity concentration in the connection portion 24 is, for example, equal to or more than 1 × 10¹¹ cm⁻³ and equal to or less than 1 × 10¹⁷ cm⁻³. When the connection portion 24 is a p-type polycrystalline silicon, the p-type impurity concentration in the connection portion 24 is, for example, equal to or more than 1 × 10¹¹ cm⁻³ and equal to or less than 1 × 10¹⁷ cm⁻³.

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The impurity concentration of the polycrystalline silicon at the second end E2 is, for example, higher than the impurity concentration of the polycrystalline silicon at the first end E1. The impurity concentration of the polycrystalline silicon at the second end E2 is, for example, equal to or more than 100 times and equal to or less than 1,000,000 times the impurity concentration of the polycrystalline silicon at the first end E1.

By increasing the impurity concentration of the polycrystalline silicon at the second end E2, for example, the contact resistance of the second contact plug portion 12b can be reduced.

In the MOSFET 500 according to the fifth embodiment, the electrical resistance R between the source electrode 12 and the first field plate electrode 20 is increased by providing the high-resistance connection portion 24. As a result, the occurrence of ringing during the OFF operation of the MOSFET 500 is suppressed.

### First Modification Example

A semiconductor device according to a first modification example of the fifth embodiment is different from the semiconductor device according to the fifth embodiment in that the connection portion further includes a fifth portion.

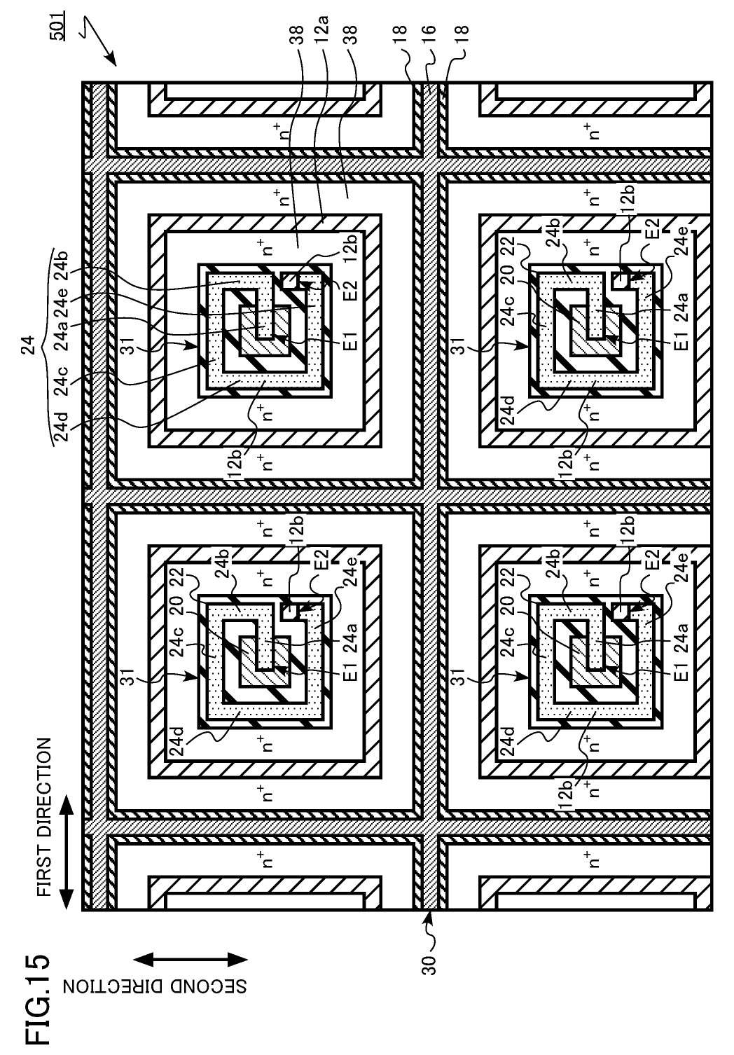

FIG. 15 is a schematic top view of the semiconductor device according to the first modification example of the fifth embodiment. FIG. 15 is a diagram showing a state in which the surface layer portion 12c of the source electrode 12 and the interlayer insulating layer 28 are removed. FIG. 15 is a diagram corresponding to FIG. 14 in the fifth embodiment.

The connection portion 24 has a first end E1 and a second end E2. The connection portion 24 includes a first portion 24a, a second portion 24b, a third portion 24c, a fourth portion 24d, and a fifth portion 24e.

The connection portion 24 extends in a direction parallel to the first face F1. For example, the first portion 24a of the connection portion 24 extends in the first direction. For example, the second portion 24b of the connection portion 24 extends in the second direction. For example, the third portion 24c of the connection portion 24 extends in the first direction. For example, the fourth portion 24d of the connection portion 24 extends in the second direction. For example, the fifth portion 24e of the connection portion 24 extends in the first direction.

### Second Modification Example

A semiconductor device according to a second modification example of the fifth embodiment is different from the semiconductor device according to the fifth embodiment in that the connection portion 24 does not include the second portion 24b, the third portion 24c, and the fourth portion 24d.

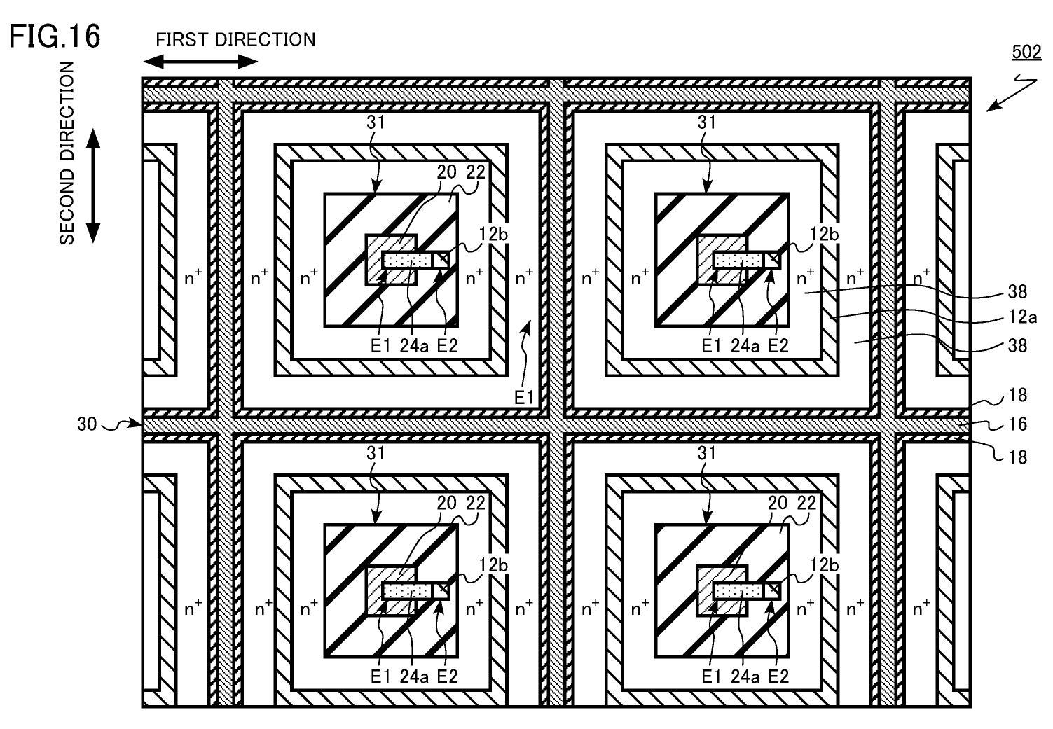

FIG. 16 is a schematic top view of the semiconductor device according to the second modification example of the fifth embodiment. FIG. 16 is a diagram showing a state in which the surface layer portion 12c of the source electrode 12 and the interlayer insulating layer 28 are removed. FIG. 16 is a diagram corresponding to FIG. 14 in the fifth embodiment.

The connection portion 24 has a first end E1 and a second end E2. The connection portion 24 includes a first portion 24a.

The connection portion 24 extends in a direction parallel to the first face F1. For example, the first portion 24a of the connection portion 24 extends in the first direction.

### Third Modification Example

A semiconductor device according to a third modification example of the fifth embodiment is different from the semiconductor device according to the fifth embodiment in that the material of the connection portion is different from the material of the first field plate electrode.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The material of the connection portion 24 is different from the material of the first field plate electrode 20. The material of the connection portion 24 is, for example, a material different from polycrystalline silicon. The material of the connection portion 24 is, for example, a silicon nitride or a silicon oxynitride. The material of the connection portion 24 is, for example, a semi-insulating silicon nitride (SinSiN).

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The electrical resistivity of the material of the connection portion 24 is larger than the electrical resistivity of the first field plate electrode 20.

As described above, according to the fifth embodiment and its modification examples, it is possible to realize a MOSFET capable of suppressing ringing.

### Sixth Embodiment

A semiconductor device according to a sixth embodiment is different from the semiconductor device according to the first embodiment in that the semiconductor layer further includes a second trench provided on the first face side and surrounded by a gate trench, the gate trench being provided between the first trench and the second trench, and a second field plate electrode provided in the second trench and in contact with the first electrode and a second field plate insulating layer provided between the second field plate electrode and the semiconductor layer are further provided. Hereinafter, the description of a part of the content overlapping the first to fifth embodiments may be omitted.

The semiconductor device according to the sixth embodiment is a vertical transistor in which a gate electrode and a field plate electrode are buried in a trench. The semiconductor device according to the sixth embodiment is a vertical power MOSFET. The semiconductor device according to the sixth embodiment is a MOSFET 600.

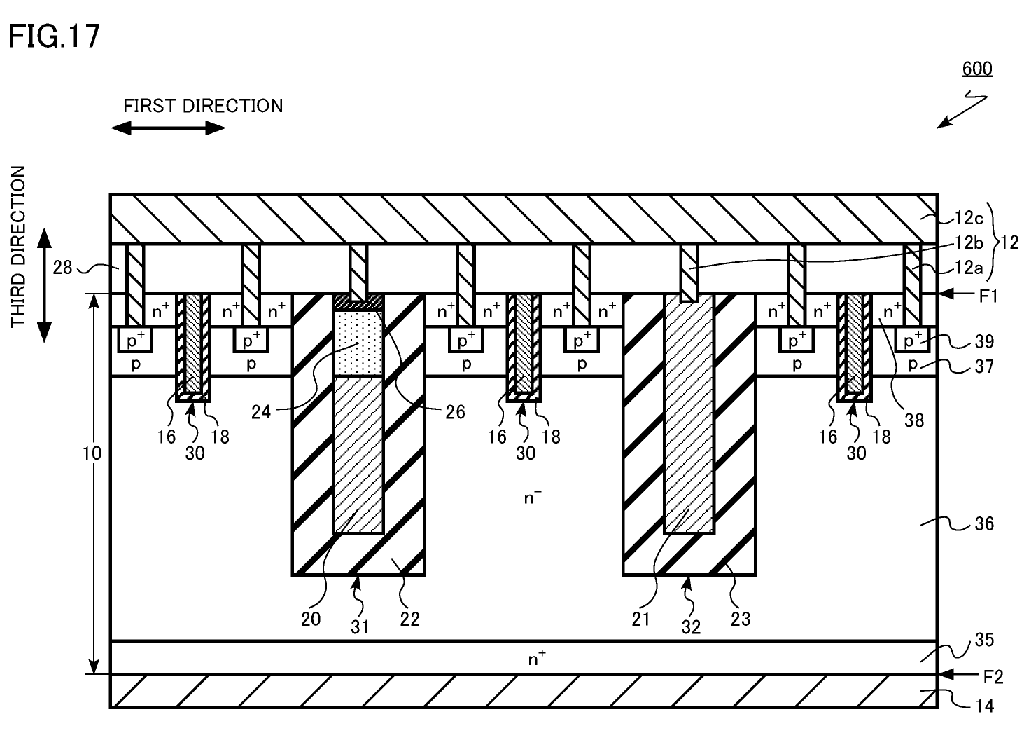

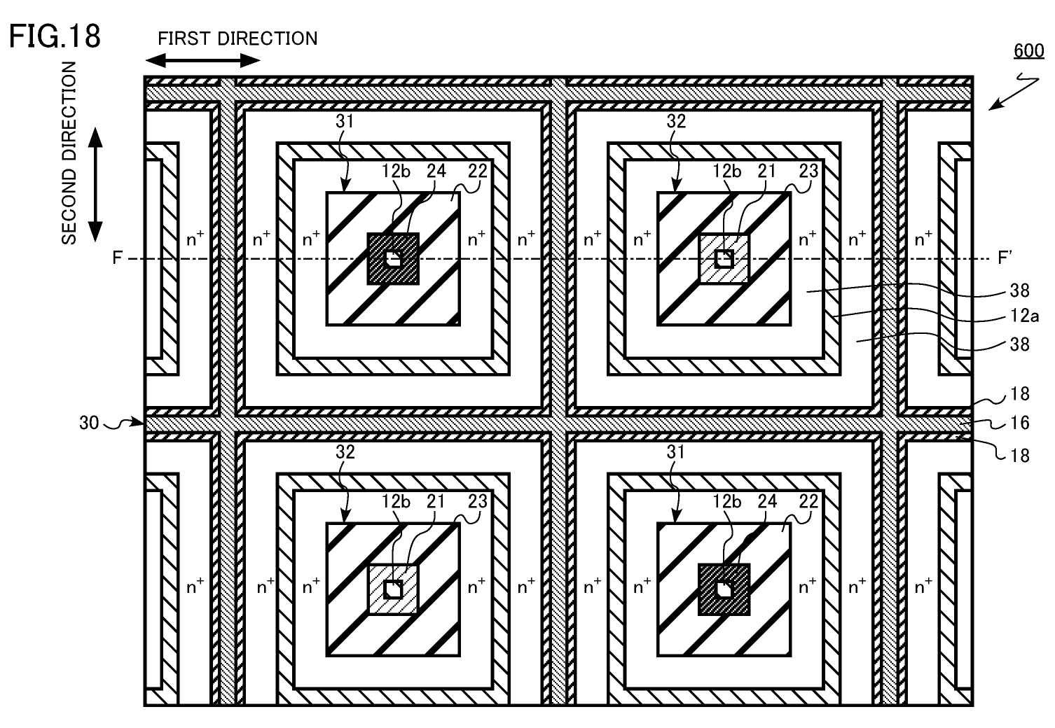

FIG. 17 is a schematic cross-sectional view of the semiconductor device according to the sixth embodiment. FIG. 18 is a schematic plan view of the semiconductor device according to the sixth embodiment. FIG. 18 is a plan view of a first face (F1 in FIG. 17) in FIG. 17. FIG. 17 is a cross-sectional view taken along the line FF' of FIG. 18.

FIG. 17 is a diagram corresponding to FIG. 1 in the first embodiment. FIG. 18 is a diagram corresponding to FIG. 2 in the first embodiment.

The MOSFET 600 includes a silicon layer 10 (semiconductor layer), a source electrode 12 (first electrode), a drain electrode 14 (second electrode), a gate electrode 16, a gate insulating layer 18, a first field plate electrode 20, a second field plate electrode 21, a first field plate insulating layer 22, a second field plate insulating layer 23, a connection portion 24, a contact portion 26, and an interlayer insulating layer 28 (first insulating layer).

The source electrode 12 includes a first contact plug portion 12a, a second contact plug portion 12b, and a surface layer portion 12c.

The silicon layer 10 includes a gate trench 30, a first field plate trench 31 (first trench), a second field plate trench 32 (second trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The gate trench 30 surrounds the first field plate trench 31. The gate trench 30 surrounds the second field plate trench 32. The gate trench 30 has a mesh shape on the first face F1.

The gate electrode 16 is provided in the gate trench 30. A gate insulating layer 18 is provided between the gate electrode 16 and the silicon layer 10.

The first field plate trench 31 is provided in the silicon layer 10. The first field plate trench 31 is provided on the first face F1 side of the silicon layer 10. The first field plate trench 31 is a groove formed in the silicon layer 10.

As shown in FIG. 18, the first field plate trench 31 is provided in a dot pattern on the first face F1. The first field plate trench 31 is surrounded by the gate trench 30. The first field plate trench 31 is deeper than the gate trench 30.

The first field plate electrode 20 is provided in the first field plate trench 31.

The first field plate electrode 20 is electrically connected to the source electrode 12.

The first field plate electrode 20 contains polycrystalline silicon. The first field plate electrode 20 is, for example, a polycrystalline silicon containing impurities. The first field plate electrode 20 is, for example, a polycrystalline silicon containing n-type impurities or p-type impurities. The first field plate electrode 20 is, for example, an n-type polycrystalline silicon or a p-type polycrystalline silicon.

The first field plate insulating layer 22 is provided between the first field plate electrode 20 and the silicon layer 10. The first field plate insulating layer 22 is provided between the first field plate electrode 20 and the drift region 36. The first field plate insulating layer 22 is, for example, a silicon oxide.

The connection portion 24 is provided between the source electrode 12 and the first field plate electrode 20. The connection portion 24 electrically connects the source electrode 12 and the first field plate electrode 20 to each other. The connection portion 24 is provided in the first field plate trench 31.

The electrical resistance of the connection portion 24 is higher than the electrical resistance of the first field plate electrode 20. The electrical resistance of the connection portion 24 is, for example, equal to or more than 100 times and equal to or less than 10,000 times the electrical resistance of the first field plate electrode 20.

The connection portion 24 contains polycrystalline silicon. The connection portion 24 is, for example, a polycrystalline silicon containing impurities. The connection portion 24 is, for example, a polycrystalline silicon containing n-type impurities or p-type impurities. The connection portion 24 is, for example, an n-type polycrystalline silicon or a p-type polycrystalline silicon.

The impurity concentration of the polycrystalline silicon in the connection portion 24 is lower than the impurity concentration of the polycrystalline silicon in the first field plate electrode 20. The impurity concentration of the polycrystalline silicon in the connection portion 24 is, for example, equal to or less than 1/100 of the impurity concentration of the polycrystalline silicon in the first field plate electrode 20.

The contact portion 26 is provided between the source electrode 12 and the connection portion 24. The contact portion 26 electrically connects the source electrode 12 and the connection portion 24 to each other.

The contact portion 26 is in contact with the source electrode 12. The contact portion 26 is in contact with the second contact plug portion 12b of the source electrode 12. The contact portion 26 is in contact with the connection portion 24. The contact portion 26 is provided in the first field plate trench 31.

The contact portion 26 contains polycrystalline silicon. The contact portion 26 is, for example, a polycrystalline silicon containing impurities. The contact portion 26 is, for example, a polycrystalline silicon containing n-type impurities or p-type impurities. The contact portion 26 is, for example, an n-type polycrystalline silicon or a p-type polycrystalline silicon.

The impurity concentration of the polycrystalline silicon in the contact portion 26 is higher than the impurity concentration of the polycrystalline silicon in the first field plate electrode 20, for example.

By providing the contact portion 26, for example, the contact resistance of the second contact plug portion 12b can be reduced.

The second field plate trench 32 is provided in the silicon layer 10. The second field plate trench 32 is provided on the first face F1 side of the silicon layer 10. The second field plate trench 32 is a groove formed in the silicon layer 10.

As shown in FIG. 18, the second field plate trench 32 is provided in a dot pattern on the first face F1. The second field plate trench 32 is surrounded by the gate trench 30. The second field plate trench 32 is deeper than the gate trench 30.

The gate trench 30 is provided between the first field plate trench 31 and the second field plate trench 32. The arrangement pattern of the first field plate trench 31 and the second field plate trench 32 is, for example, a checkerboard pattern as shown in FIG. 18.

The second field plate electrode 21 is provided in the second field plate trench 32.

The second field plate electrode 21 is electrically connected to the source electrode 12. The second field plate electrode 21 is in contact with the source electrode 12. The second field plate electrode 21 is in contact with the second contact plug portion 12b of the source electrode 12.

The second field plate electrode 21 contains polycrystalline silicon. The second field plate electrode 21 is, for example, a polycrystalline silicon containing impurities. The second field plate electrode 21 is, for example, a polycrystalline silicon containing n-type impurities or p-type impurities. The second field plate electrode 21 is, for example, an n-type polycrystalline silicon or a p-type polycrystalline silicon.

The material of the second field plate electrode 21 is, for example, the same material as the material of the first field plate electrode 20.

The second field plate insulating layer 23 is provided between the second field plate electrode 21 and the silicon layer 10. The second field plate insulating layer 23 is provided between the second field plate electrode 21 and the drift region 36. The second field plate insulating layer 23 is, for example, a silicon oxide.

Between the source electrode 12 and the second field plate electrode 21, no connection portion 24 is provided.

If the electrical resistance R of the snubber circuit of the MOSFET is too high, there is a risk that the switching loss of the MOSFET will increase. The MOSFET 600 according to the sixth embodiment has a region including the first field plate trench 31 with a high electrical resistance R between the source electrode 12 and the first field plate electrode 20 and a region including the second field plate trench 32 with a low electrical resistance R between the source electrode 12 and the second field plate electrode 21. This configuration enables both suppression of ringing and reduction of switching loss.

In addition, although the case where the arrangement pattern of the first field plate trench 31 and the second field plate trench 32 is a checkerboard pattern has been described as an example, the arrangement pattern of the first field plate trench 31 and the second field plate trench 32 is not limited to the checkerboard pattern. For example, it is also possible to change the ratio of the presence of the first field plate trenches 31 and the second field plate trenches 32.

As described above, according to the sixth embodiment, it is possible to realize a MOSFET capable of suppressing ringing.

### Seventh Embodiment

A semiconductor device according to a seventh embodiment includes: a semiconductor layer having a first face and a second face opposite to the first face and including a first trench provided on a side of the first face, a gate trench provided on the first face side and surrounding the first trench, a first semiconductor region of a first conductive type, a second semiconductor region of a second conductive type provided between the first semiconductor region and the first face, and a third semiconductor region of the first conductive type provided between the second semiconductor region and the first face; a first field plate electrode provided in the first trench and containing first polycrystalline silicon; a first field plate insulating layer provided between the first field plate electrode and the semiconductor layer; a gate electrode provided in the gate trench and containing second polycrystalline silicon; a gate insulating layer provided between the gate electrode and the semiconductor layer; a first electrode provided on the first face side of the semiconductor layer and electrically connected to the third semiconductor region and the first field plate electrode; and a second electrode provided on a side of the second face of the semiconductor layer and electrically connected to the first semiconductor region. An impurity concentration of the first polycrystalline silicon is lower than an impurity concentration of the second polycrystalline silicon.

The semiconductor device according to the seventh embodiment is different from the semiconductor device according to the first embodiment in that the semiconductor device according to the seventh embodiment does not include a connection portion and a contact portion. Hereinafter, the description of a part of the content overlapping the first embodiment may be omitted.

The semiconductor device according to the seventh embodiment is a vertical transistor in which a gate electrode and a field plate electrode are buried in a trench. The semiconductor device according to the seventh embodiment is a vertical power MOSFET. The semiconductor device according to the seventh embodiment is a MOSFET 700.

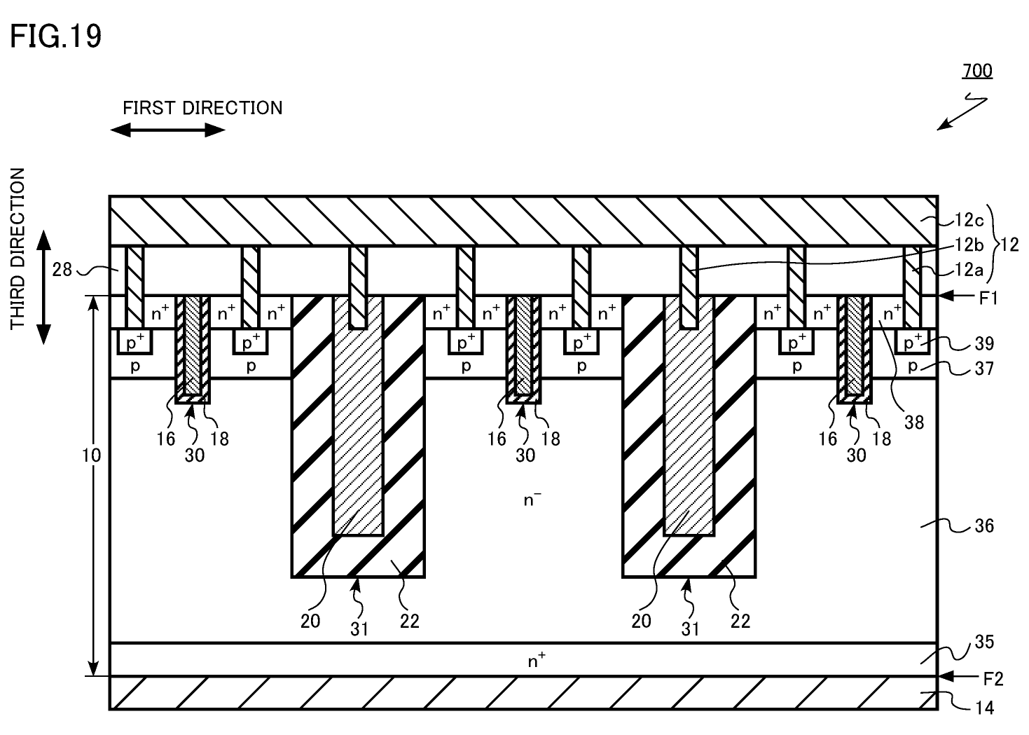

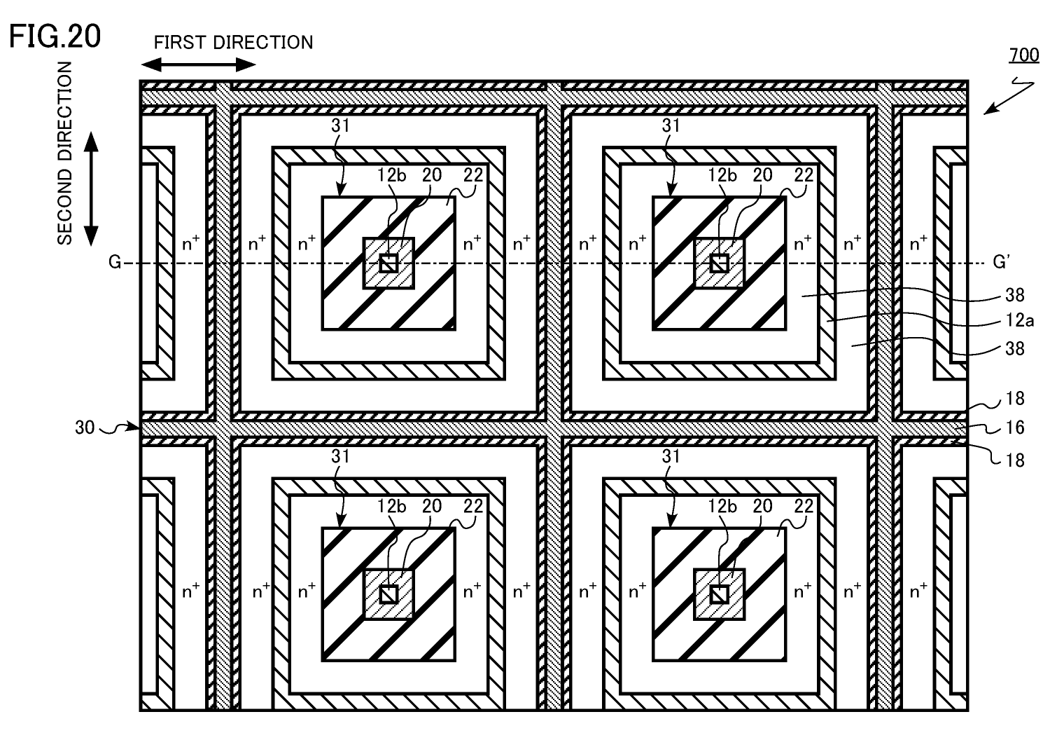

FIG. 19 is a schematic cross-sectional view of the semiconductor device according to the seventh embodiment. FIG. 20 is a schematic plan view of the semiconductor device according to the seventh embodiment. FIG. 20 is a plan view of a first face (F1 in FIG. 19) in FIG. 19. FIG. 19 is a cross-sectional view taken along the line GG' of FIG. 20.

The MOSFET 700 includes a silicon layer 10 (semiconductor layer), a source electrode 12 (first electrode), a drain electrode 14 (second electrode), a gate electrode 16, a gate insulating layer 18, a first field plate electrode 20, a first field plate insulating layer 22, and an interlayer insulating layer 28 (first insulating layer).

The source electrode 12 includes a first contact plug portion 12a, a second contact plug portion 12b, and a surface layer portion 12c.

The silicon layer 10 includes a gate trench 30, a first field plate trench 31 (first trench), an n⁺-type drain region 35, an n⁻-type drift region 36 (first semiconductor region), a p-type body region 37 (second semiconductor region), an n⁺-type source region 38 (third semiconductor region), and a p⁺-type contact region 39.

The gate trench 30 is provided in the silicon layer 10. The gate trench 30 is provided on the first face F1 side of the silicon layer 10. The gate trench 30 is a groove formed in the silicon layer 10.

The gate trench 30 surrounds the first field plate trench 31. The gate trench 30 has a mesh shape on the first face F1.

The gate electrode 16 is provided in the gate trench 30. The gate insulating layer 18 is provided between the gate electrode 16 and the silicon layer 10.

The gate electrode 16 contains, for example, second polycrystalline silicon. The second polycrystalline silicon is, for example, a polycrystalline silicon containing n-type impurities or p-type impurities. The second polycrystalline silicon is, for example, an n-type polycrystalline silicon or a p-type polycrystalline silicon.

The impurity concentration of the second polycrystalline silicon is, for example, equal to or more than 1 × 10¹⁹ cm⁻³ and equal to or less than 1 × 10²² cm⁻³. When the second polycrystalline silicon is an n-type polycrystalline silicon, the n-type impurity concentration of the second polycrystalline silicon is, for example, equal to or more than 1 × 10¹⁹ cm⁻³ and equal to or less than 1 × 10²² cm⁻³. When the second polycrystalline silicon is a p-type polycrystalline silicon, the p-type impurity concentration of the second polycrystalline silicon is, for example, equal to or more than 1 × 10¹⁹ cm⁻³ and equal to or less than 1 × 10²² cm⁻³.

The gate electrode 16 may have a stacked structure of, for example, a polycrystalline silicon layer containing the second polycrystalline silicon and a metal layer.

The first field plate trench 31 is provided in the silicon layer 10. The first field plate trench 31 is provided on the first face F1 side of the silicon layer 10. The first field plate trench 31 is a groove formed in the silicon layer 10.

As shown in FIG. 20, the first field plate trench 31 is provided in a dot pattern on the first face F1. The first field plate trench 31 is surrounded by the gate trench 30. The first field plate trench 31 is deeper than the gate trench 30.

The first field plate electrode 20 is provided in the first field plate trench 31.

The first field plate electrode 20 is electrically connected to the source electrode 12.

The first field plate electrode 20 contains first polycrystalline silicon. The first polycrystalline silicon is, for example, a polycrystalline silicon containing an impurity. The first polycrystalline silicon is, for example, a polycrystalline silicon containing n-type impurities or p-type impurities. The first polycrystalline silicon is, for example, an n-type polycrystalline silicon or a p-type polycrystalline silicon.

The impurity concentration of the first polycrystalline silicon is, for example, equal to or more than 1 × 10¹¹ cm⁻³ and equal to or less than 1 × 10¹⁸ cm⁻³. When the first polycrystalline silicon is an n-type polycrystalline silicon, the n-type impurity concentration of the first polycrystalline silicon is, for example, equal to or more than 1 × 10¹¹ cm⁻³ and equal to or less than 1 × 10¹⁸ cm⁻³. When the first polycrystalline silicon is a p-type polycrystalline silicon, the p-type impurity concentration of the first polycrystalline silicon is, for example, equal to or more than 1 × 10¹¹ cm⁻³ and equal to or less than 1 × 10¹⁸ cm⁻³.

The impurity concentration of the first polycrystalline silicon is lower than the impurity concentration of the second polycrystalline silicon. The impurity concentration of the first polycrystalline silicon is, for example, equal to or less than 1/100 of the impurity concentration of the second polycrystalline silicon.

The electrical resistivity of the first polycrystalline silicon is larger than the electrical resistivity of the second polycrystalline silicon. The electrical resistivity of the first polycrystalline silicon is, for example, equal to or more than 100 times the electrical resistivity of the second polycrystalline silicon.

The source electrode 12 is provided on the first face F1 side of the silicon layer 10. The source electrode 12 is provided on the first face F1 of the silicon layer 10.

The source electrode 12 is electrically connected to the source region 38. The source electrode 12 is electrically connected to the first field plate electrode 20.

The source electrode 12 includes a first contact plug portion 12a, a second contact plug portion 12b, and a surface layer portion 12c.

The first contact plug portion 12a is provided, for example, between the silicon layer 10 and the surface layer portion 12c. The first contact plug portion 12a is in contact with, for example, the silicon layer 10. The first contact plug portion 12a is in contact with, for example, the contact region 39. For example, the bottom surface of the first contact plug portion 12a is in contact with the contact region 39.

The first contact plug portion 12a is in contact with, for example, the source region 38. For example, the side surface of the first contact plug portion 12a is in contact with the source region 38.

A part of the first contact plug portion 12a fills, for example, a recess provided in the silicon layer 10. A part of the first contact plug portion 12a is provided, for example, in a recess provided in the silicon layer 10.

The second contact plug portion 12b is provided, for example, between the first field plate electrode 20 and the surface layer portion 12c. The second contact plug portion 12b is in contact with, for example, the first field plate electrode 20.

A part of the second contact plug portion 12b fills, for example, a recess provided in the first field plate electrode 20. A part of the second contact plug portion 12b is provided, for example, in a recess provided in the first field plate electrode 20.

Hereinafter, the function and effect of the semiconductor device according to the seventh embodiment will be described.

If the electrical resistance R of the snubber circuit of the MOSFET is low, ringing during the OFF operation cannot be suppressed. For this reason, ringing may occur in the MOSFET. When ringing occurs in the MOSFET, for example, the current flowing through the electronic circuit including the MOSFET increases, causing a problem in that the power consumption of the electronic circuit increases.

In the MOSFET 700 according to the seventh embodiment, the impurity concentration of the first polycrystalline silicon contained in the first field plate electrode 20 is lower than the impurity concentration of the second polycrystalline silicon contained in the gate electrode 16. Therefore, the electrical resistance R between the source electrode 12 and the first field plate electrode 20 increases. As a result, the occurrence of ringing during the OFF operation of the MOSFET 700 is suppressed.

From the viewpoint of suppressing ringing, the impurity concentration of the first polycrystalline silicon is preferably equal to or less than 1/100, more preferably equal to or less than 1/1000, and even more preferably equal to or less than 1/10,000 of the impurity concentration of the second polycrystalline silicon.

From the viewpoint of suppressing ringing, the impurity concentration of the first polycrystalline silicon is preferably equal to or less than 1 × 10¹⁸ cm⁻³, more preferably equal to or less than 1 × 10¹⁷ cm⁻³, and even more preferably equal to or less than 1 × 10¹⁶ cm⁻³.

As described above, according to the seventh embodiment, it is possible to realize a MOSFET capable of suppressing ringing.

As described above, in the first to seventh embodiments, the case where the first conductive type is n-type and the second conductive type is p-type has been described as an example. However, the first conductive type can be p-type and the second conductive type can be n-type.

In addition, in the first to seventh embodiments, the case where the material of the first field plate electrode 20 is a polycrystalline silicon has been described as an example, but the material of the first field plate electrode 20 is not necessarily limited to the polycrystalline silicon.

In addition, in the first to seventh embodiments, the case is shown in which the shape of the first face F1 of the gate trench 30 is a quadrangular mesh shape, but the shape of the gate trench 30 may be other polygonal mesh shapes, such as a hexagonal mesh shape or an octagonal mesh shape.

In addition, in the first to seventh embodiments, silicon has been described as an example of the semiconductor material, but other semiconductor materials such as silicon carbide (SiC) and gallium nitride (GaN) can also be used.

In addition, in the sixth embodiment, the case where the structure of the connection portion 24 is the structure of the connection portion 24 in the first embodiment has been described as an example. However, in the sixth embodiment, the structure of the connection portion 24 is not limited to the structure of the connection portion 24 in the first embodiment, and can be, for example, the structure of the connection portion 24 in the second to fifth embodiments.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer having a first face and a second face opposite to the first face and including a first trench provided on a first face side, a gate trench provided on the first face side and surrounding the first trench, a first semiconductor region of a first conductive type, a second semiconductor region of a second conductive type provided between the first semiconductor region and the first face, and a third semiconductor region of the first conductive type provided between the second semiconductor region and the first face;
a first field plate electrode provided in the first trench;
a first field plate insulating layer provided between the first field plate electrode and the semiconductor layer;
a gate electrode provided in the gate trench;
a gate insulating layer provided between the gate electrode and the semiconductor layer;
a first electrode provided on a side of the first face of the semiconductor layer and electrically connected to the third semiconductor region and the first field plate electrode;
a second electrode provided on a side of the second face of the semiconductor layer and electrically connected to the first semiconductor region; and
a connection portion provided between the first electrode and the first field plate electrode, electrically connected to the first electrode and the first field plate electrode, and having an electrical resistance higher than an electrical resistance of the first field plate electrode.

2. The semiconductor device according to claim 1,
wherein the electrical resistance of the connection portion is equal to or more than 100 times the electrical resistance of the first field plate electrode.

3. The semiconductor device according to claim 1,
wherein an electrical resistivity of the connection portion is higher than an electrical resistivity of the first field plate electrode.

4. The semiconductor device according to claim 1,
wherein the connection portion is provided in the first trench.

5. The semiconductor device according to claim 4,
wherein the connection portion includes polycrystalline silicon,
the first field plate electrode includes polycrystalline silicon, and
an impurity concentration of polycrystalline silicon included in the connection portion is lower than an impurity concentration of polycrystalline silicon included in the first field plate electrode.

6. The semiconductor device according to claim 5, further comprising:
a contact portion provided in the first trench, provided between the connection portion and the first electrode, in contact with the connection portion and the first electrode, and including polycrystalline silicon,
wherein an impurity concentration of polycrystalline silicon included in the contact portion is higher than an impurity concentration of polycrystalline silicon included in the connection portion.

7. The semiconductor device according to claim 6,
wherein the impurity concentration of the polycrystalline silicon included in the contact portion is higher than the impurity concentration of the polycrystalline silicon included in the first field plate electrode.

8. The semiconductor device according to claim 4,
wherein a width of the connection portion in a first direction parallel to the first face is smaller than a width of the first field plate electrode in the first direction.

9. The semiconductor device according to claim 8,
wherein the connection portion includes polycrystalline silicon, and the first field plate electrode includes polycrystalline silicon.

10. The semiconductor device according to claim 4,
wherein a material of the connection portion is different from a material of the first field plate electrode.

11. The semiconductor device according to claim 1,
wherein the connection portion extends in a direction parallel to the first face,
a first end of the connection portion is connected to the first field plate electrode, and
a second end of the connection portion is connected to the first electrode.

12. The semiconductor device according to claim 11,
wherein the connection portion includes a first portion extending in a first direction parallel to the first face and a second portion extending in a second direction parallel to the first face and crossing the first direction.

13. The semiconductor device according to claim 11,
wherein the connection portion is a polycrystalline silicon, and
an impurity concentration at the second end is higher than an impurity concentration at the first end.

14. The semiconductor device according to claim 1,
wherein the semiconductor layer further includes a second trench provided on the first face side and surrounded by the gate trench, the gate trench being provided between the first trench and the second trench, and
a second field plate electrode provided in the second trench and in contact with the first electrode and a second field plate insulating layer provided between the second field plate electrode and the semiconductor layer are further provided.

15. The semiconductor device according to claim 1, further comprising:
a first insulating layer provided between the first electrode and the semiconductor layer, between the first electrode and the first field plate electrode, and between the first electrode and the gate electrode,
wherein the connection portion is surrounded by the first insulating layer.

16. A semiconductor device, comprising:
a semiconductor layer having a first face and a second face opposite to the first face and including a first trench provided on a first face side, a gate trench provided on the first face side and surrounding the first trench, a first semiconductor region of a first conductive type, a second semiconductor region of a second conductive type provided between the first semiconductor region and the first face, and a third semiconductor region of the first conductive type provided between the second semiconductor region and the first face;
a first field plate electrode provided in the first trench and including first polycrystalline silicon;
a first field plate insulating layer provided between the first field plate electrode and the semiconductor layer;
a gate electrode provided in the gate trench and including second polycrystalline silicon;
a gate insulating layer provided between the gate electrode and the semiconductor layer;
a first electrode provided on a side of the first face of the semiconductor layer and electrically connected to the third semiconductor region and the first field plate electrode; and
a second electrode provided on a side of the second face of the semiconductor layer and electrically connected to the first semiconductor region,
wherein an impurity concentration of the first polycrystalline silicon is lower than an impurity concentration of the second polycrystalline silicon.

17. The semiconductor device according to claim 16,
wherein the impurity concentration of the first polycrystalline silicon is equal to or less than 1/100 of the impurity concentration of the second polycrystalline silicon.

18. The semiconductor device according to claim 16,
wherein the impurity concentration of the first polycrystalline silicon is equal to or less than 1 × 10¹⁸ cm⁻³ and the impurity concentration of the second polycrystalline silicon is equal to or more than 1 × 10²⁰ cm⁻³.
